(19) United States
(12) Patent Application Publication
(10) Pub. No.: US 2020/0075663 A1
(43) Pub. Date: Mar. 5, 2020

(54) LIGHT EMITTING DEVICE

(71) Applicant: TOSHIBA HOKUTO ELECTRONICS CORPORATION, Asahikawa-Shi (JP)

(72) Inventors: Koichi MATSUSHITA, Asahikawa (JP); Akira ISHIGAI, Asahikawa (JP); Takamasa OOTAKE, Kawasaki (JP)

(73) Assignee: TOSHIBA HOKUTO ELECTRONICS CORPORATION, Asahikawa-Shi (JP)

(21) Appl. No.: 16/454,783

(22) Filed: Jun. 27, 2019

(30) Foreign Application Priority Data
Sep. 3, 2018 (JP) 2018-164963

(51) Int. Cl. H01L 27/15; H01L 33/52

(52) U.S. Cl. CPC H01L 27/153; H01L 33/52

(57) ABSTRACT

A light emitting device according to this embodiment, includes: a first substrate having light transmittivity and flexibility, a conductor layer being formed on the first substrate; a second substrate having light transmittivity and flexibility, and being arranged to face the first substrate; a plurality of light emitting elements including an electrode connected to the conductor layer, and being arranged between the first substrate and the second substrate into the shape of a matrix; and a resin layer having light transmittivity and flexibility, and retaining the plurality of light emitting elements by being arranged between the first substrate and the second substrate, the plurality of light emitting elements configuring a point light source, in which a distance between the point light sources adjacent to each other is 0.3 cm to 3.2 cm.

### TECHNICAL FIELD

An embodiment of the present invention relates to a light emitting device.

### BACKGROUND

Recently, an effort for reducing energy consumption has been emphasized. From such a background, a light emitting diode (LED) having comparatively small power consumption has attracted attention as a next-generation light source. The LED has a small size and a small calorific value, and also has excellent responsiveness. For this reason, the LED has been widely used in various optical devices. For example, recently, a light emitting device including an LED arranged on a substrate having flexibility and translucency as a light source has been proposed. In the light emitting device, it is desirable that an object such as an image or a body on a rear side is visible through the light emitting device not only at the time of being turned off, but also at the time of being turned on.

However, in the light emitting device described above, light exits from the LED through the substrate having transmittivity, an intermediate resin retaining the LED with respect to the substrate, or the like. For this reason, a part of the light from the LED, or light that is diffusely reflected on an electrode of the LED, is guided into the substrate or the intermediate resin, and leaked to the outside. The substrate or the intermediate resin is not completely transparent, and thus, in a case where light is guided into the substrate or the intermediate resin, a portion different from a point light source looks blurred. For this reason, in a case where an object is observed through the light emitting device that is turned on, the object looks blurred.

In addition, in a case where the point light source is arranged into the shape of a matrix, and the light emitting device is obliquely seen, the adjacent point light sources look overlapping with each other, or light of a sufficient intensity does not reach in a direction where an observer is positioned.

Patent Document 1: JP 2012-084855 A

### SUMMARY

The invention has been made in consideration of the circumstances described above, and an object thereof is to improve the visibility of a light emitting device, and to improve the visibility of an object through the light emitting device having light transmittivity.

In order to attain the object described above, a light emitting device according to this embodiment includes: a first substrate having light transmittivity and flexibility, and a conductor layer being formed on the first substrate; a second substrate having light transmittivity and flexibility, and being arranged to face the first substrate; a plurality of light emitting elements including an electrode connected to the conductor layer, being arranged between the first substrate and the second substrate into the shape of a matrix, and configuring a point light source; and a resin layer having light transmittivity and flexibility, being arranged between the first substrate and the second substrate, and retaining the plurality of light emitting elements, in which a distance between the point light sources adjacent to each other is 0.3 cm to 3.2 cm.

### BRIEF DESCRIPTION OF THE DRAWINGS

FIG. 1 is a plan view of a light emitting device according to this embodiment;

FIG. 2 is a plan view illustrating a point light source;

FIG. 3 is a perspective view illustrating an example of a light emitting element;

FIG. 4 is a diagram illustrating an A-A sectional surface of the light emitting device;

FIG. 5 is a plan view of a conductor pattern;

FIG. 6 is a diagram enlargedly illustrating the vicinity of the point light source;

FIG. 7 is a diagram illustrating a circuit formed by allowing a flexible cable to adhere to a light emitting panel;

FIG. 8 is a diagram for illustrating an array of the point light sources;

FIG. 9 is a diagram illustrating a text that is displayed on the light emitting panel;

FIG. 10 is a diagram schematically illustrating radiant light exiting from the light emitting element by using an arrow;

FIG. 11 is a diagram illustrating a light distribution curve representing a light distribution of the radiant light exiting from the light emitting element;

FIG. 12 is a diagram illustrating an actual light distribution curve of the light emitting element;

FIG. 13 is a diagram illustrating a light distribution curve of the light emitting device;

FIG. 14 is a diagram for illustrating an observation point of an object;

FIG. 15 is a diagram for illustrating the observation point of the object;

FIG. 16 is a diagram for illustrating the observation point of the object;

FIG. 17 is an image diagram when an illustration of paper is observed;

FIG. 18 is an image diagram when the illustration of the paper is observed;

FIG. 19 is an image diagram when the illustration of the paper is observed;

FIG. 20 is an image diagram when the illustration of the paper is observed;

FIG. 21 is a diagram illustrating a test result of visibility when the illustration of the paper is observed;

FIG. 22 is a plan view of the light emitting panel;

FIG. 23 is a diagram illustrating a graph in which a result illustrated in a picture is digitized;

FIG. 24 is a diagram illustrating the graph in which the result illustrated in the picture is digitized;

FIG. 25 is a diagram illustrating the graph in which the result illustrated in the picture is digitized;

FIG. 26 is a diagram illustrating the graph in which the result illustrated in the picture is digitized;

FIG. 27 is a diagram illustrating a mesh pattern;

FIG. 28 is a table showing a marginal transparency;

FIG. 29 is a diagram illustrating a consideration result of an array pitch and the mesh pattern;

FIG. 30 is a diagram for illustrating a usage mode of the light emitting device;

FIG. 31 is a diagram for illustrating the usage mode of the light emitting device;

FIG. 32 is a diagram for illustrating the usage mode of the light emitting device;

FIG. 33 is a diagram for illustrating the usage mode of the light emitting device;

FIG. 34 is a diagram for illustrating the usage mode of the light emitting device;

FIG. 35 is a diagram illustrating a modification example of the light emitting device;

FIG. 36 is a diagram illustrating the modification example of the light emitting device;

FIG. 37 is a diagram illustrating the modification example of the light emitting device;

FIG. 38 is a diagram illustrating the modification example of the light emitting device;

FIG. 39 is a picture of the object and the light emitting device;

FIG. 40 is a picture of the object and the light emitting device;

FIG. 41 is a picture of the light emitting device that is bent;

FIG. 42 is a picture of the light emitting element that is affected by the radiant light;

FIG. 43 is a picture of the light emitting element that is affected by the radiant light;

FIG. 44 is a picture of the light emitting element that is affected by the radiant light;

FIG. 45 is a picture of the light emitting element that is affected by the radiant light;

FIG. 46 is a picture illustrating the light emitting device from the side; and

FIG. 47 is a picture of the light emitting device that is folded.

### DETAILED DESCRIPTION

Hereinafter, one embodiment of the invention will be described by using the drawings. In the description, an XYZ coordinate system including an X axis, a Y axis, and a Z axis orthogonal to each other is used.

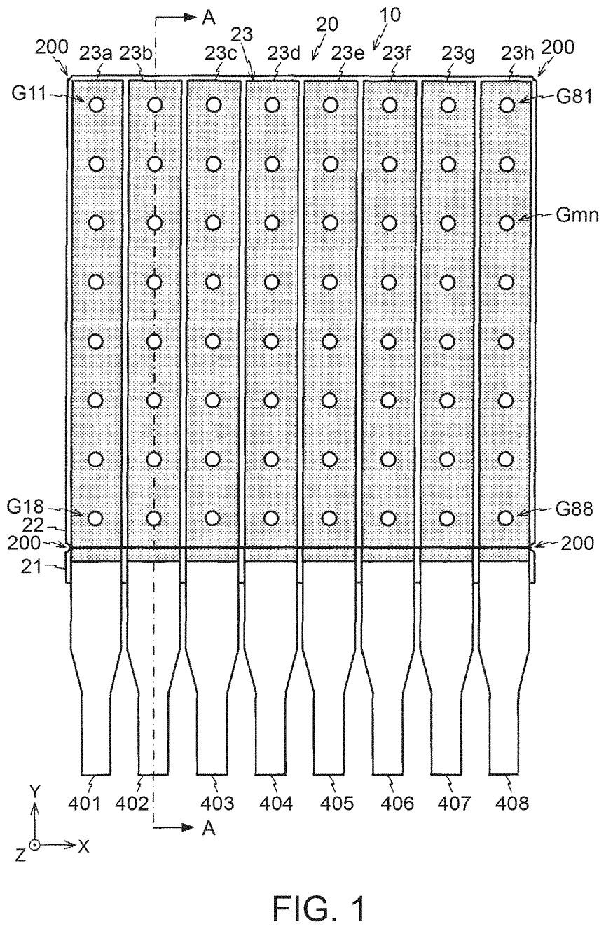

FIG. 1 is a plan view of a light emitting device 10 according to this embodiment. As illustrated in FIG. 1, the light emitting device 10 is a module in which a longitudinal direction is set to a Y axis direction. The light emitting device 10 includes a square light emitting panel 20, and eight flexible cables 401 to 408 that are connected to the light emitting panel 20.

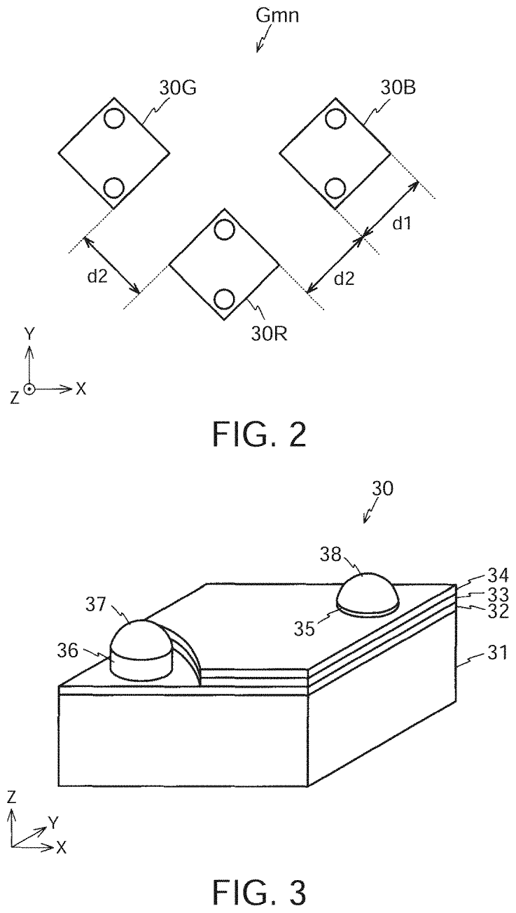

The light emitting panel 20 is a panel including 64 point light sources Gmn (=G11 to G88: m and n are an integer of 1 to 8) that are arranged into the shape of a matrix of eight rows and eight columns. The dimension light emitting panel 20 in an X axis direction and the Y axis direction is approximately 10 cm to 15 cm. FIG. 2 is a plan view illustrating the point light source Gmn. As illustrated in FIG. 2, the point light source Gmn includes three light emitting elements 30R, 30G, and 30B.

Each of the light emitting elements 30R, 30G, and 30B is a square LED chip of which one side is approximately 0.1 mm to 3 mm. In this embodiment, the light emitting elements 30R, 30G, and 30B are a bare chip. In addition, a light intensity of the light emitting elements 30R, 30G, and 30B is approximately 0.1 to 1 [lm]. Hereinafter, for the convenience of the description, the light emitting elements 30R, 30G, and 30B will be suitably and collectively referred to as a light emitting element 30.

FIG. 3 is a perspective view illustrating an example of the light emitting element 30. As illustrated in FIG. 3, the light emitting element 30 is an LED chip including a base substrate 31, an N type semiconductor layer 32, an active layer 33, and a P type semiconductor layer 34. A rated current of the light emitting element 30 is approximately 50 mA.

The base substrate 31, for example, is a square plate-like substrate formed of sapphire. The N type semiconductor layer 32 having the same shape of that of the base substrate 31 is formed on an upper surface of the base substrate 31. Then, the active layer 33 and the P type semiconductor layer 34 are laminated on an upper surface of the N type semiconductor layer 32, in this order. The N type semiconductor layer 32, the active layer 33, and the P type semiconductor layer 34 are formed of a compound semiconductor material. For example, in a light emitting element emitting red light, an InAlGaP-based semiconductor can be used as an active layer. In addition, in a light emitting element emitting blue or green light, a GaN-based semiconductor can be used as the P type semiconductor layer 34 and the N type semiconductor layer 32, and an InGaN-based semiconductor can be used as the active layer 33. In any case, the active layer may have a double hetero (DH) junction structure, or may have a multiquantum well (MQW) structure. In addition, the active layer may have a PN junction configuration.

In the active layer 33 and the P type semiconductor layer 34 that are laminated on the N type semiconductor layer 32, a notch is formed in a corner portion on a −Y side and a −X side. The surface of the N type semiconductor layer 32 is exposed from the notch of the active layer 33 and the P type semiconductor layer 34.

A pad electrode 36 that is electrically connected to the N type semiconductor layer 32 is formed in a region of the N type semiconductor layer 32 that is exposed from the active layer 33 and the P type semiconductor layer 34. In addition, an electrode 35 that is electrically connected to the P type semiconductor layer 34 is formed in a corner portion of the P type semiconductor layer 34 on a +X side and a +Y side. The electrodes 35 and 36 are formed of copper (Cu) or gold (Au), and bumps 37 and 38 are formed on an upper surface. The bumps 37 and 38 are a metal bump formed of a metal such as gold (Au) or a gold alloy. A solder bump that is molded into the shape of a half-sphere may be used instead of the metal bump. In the light emitting element 30, the bump 37 functions as a cathode electrode, and the bump 38 functions as an anode electrode.

The light emitting element 30R illustrated in FIG. 2 emits red light. In addition, the light emitting element 30G emits green light, and the light emitting element 30B emits blue light. Specifically, the light emitting element 30R allows light having a peak wavelength of approximately 600 nm to 700 nm to exit. In addition, the light emitting element 30G allows light having a peak wavelength of approximately 500 nm to 550 nm to exit. Then, the light emitting element 30B allows light having a peak wavelength of approximately 450 nm to 500 nm to exit.

In the light emitting elements 30R, 30G, and 30B configured as described above, the light emitting elements 30G and 30B are arranged to be adjacent to light emitting element 30R. In addition, the light emitting elements 30R, 30G, and 30B are arranged to be close to each other such that a distance d2 to the adjacent light emitting elements 30R, 30G, and 30B is less than or equal to a width d1 of the light emitting elements 30R, 30G, and 30B.

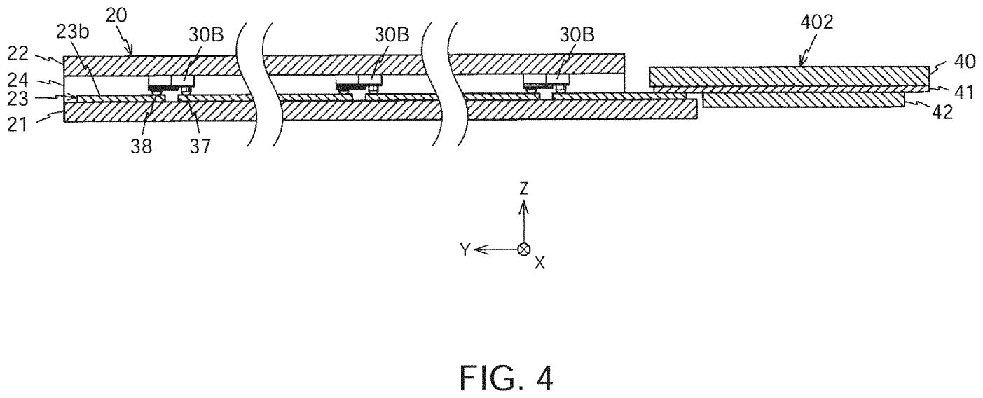

FIG. 4 is a diagram illustrating an A-A sectional surface of the light emitting device 10 in FIG. 1. As known with reference to FIG. 4, the light emitting panel 20 configuring the light emitting device 10 includes the light emitting elements 30R, 30G, and 30B described above, a set of substrates 21 and 22, and a resin layer 24 that is formed between the substrates 21 and 22. Furthermore, FIG. 4 illustrates only the light emitting element 30B.

The substrate 21 is a film-like member in which the longitudinal direction is set as the Y axis direction. In addition, the substrate 22 is a square film-like member. The substrates 21 and 22 have a thickness of approximately 50 μm to 300 μm, and have transmittivity with respect to visible light. It is preferable that a total light transmittance of the substrates 21 and 22 is approximately 5% to 95%. Furthermore, the total light transmittance indicates a total light transmittance that is measured on the basis of Japanese Industrial Standards JISK7375:2008.

The substrates 21 and 22 have flexibility, and have a bending elastic modulus of approximately 0 kgf/mm² to 320 kgf/mm² (excluding 0). Furthermore, the bending elastic modulus is a value that is measured by a method based on ISO178 (JIS K7171:2008).

It is considered that polyethylene terephthalate (PET), polyethylene naphthalate (PEN), polycarbonate (PC), polyethylene succinate (PES), ARTON, an acrylic resin, and the like are used as a material of the substrates 21 and 22.

In the set of substrates 21 and 22 described above, a conductor layer 23 having a thickness of approximately 0.05 μm to 10 μm is formed on an upper surface of the substrate 21 (a surface on a −Z side in FIG. 4). The conductor layer 23, for example, is a vapor-deposited film or a sputtering film. In addition, the conductor layer 23 may be formed by pasting a metal film with an adhesive agent. In a case where the conductor layer 23 is the vapor-deposited film or the sputtering film, the thickness of the conductor layer 23 is approximately 0.05 μm to 2 μm. In a case where the conductor layer 23 is the pasted metal film, the thickness of the conductor layer 23 is approximately 2 μm to 10 μm or 2 μm to 7 μm.

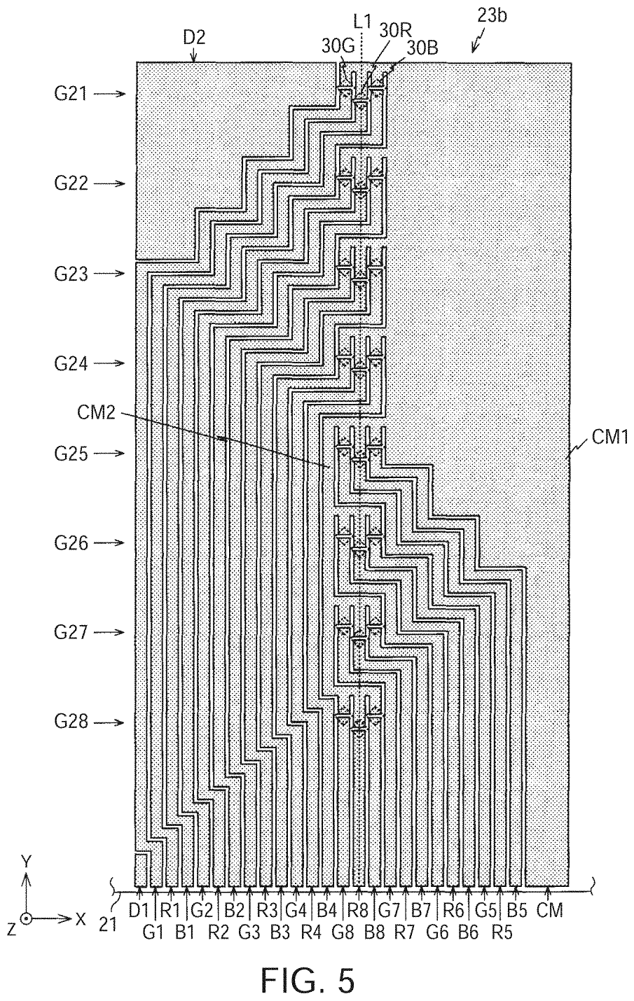

The conductor layer 23 is a metal layer formed of a metal material such as copper (Cu) or silver (Ag). As illustrated in FIG. 1, the conductor layer 23 is configured of eight conductor patterns 23a to 23h in which the longitudinal direction is set to the Y axis direction. FIG. 5 is a plan view of the conductor pattern 23b illustrated in FIG. 4. As illustrated in FIG. 5, the conductor pattern 23b includes 24 individual line patterns G1 to G8, R1 to R8, and B1 to B8, a common line pattern CM, and two dummy line patterns D1 and D2.

In the individual line patterns G1 to G8, one end is connected to each cathode of the light emitting element 30G configuring each of point light sources G21 to G28. Then, the other end is drawn around in an end portion of the substrate 21 on the −Y side. Similarly, in the individual line patterns R1 to R8, one end is connected to each cathode of the light emitting element 30R configuring each of the point light sources G21 to G28. Then, the other end is drawn around in the end portion of the substrate 21 on the −Y side. In addition, in the individual line patterns B1 to B8, one end is connected to each cathode of light emitting element 30B configuring each of the point light sources G21 to G28. Then, the other end is drawn around in the end portion of the substrate 21 on the −Y side.

In the common line pattern CM, one end is branched into plurality of ends, and is connected to each anode of the light emitting elements 30R, 30G, and 30B configuring each of the point light sources G21 to G28. In addition, the other end is drawn around in the end portion of the substrate 21 on the −Y side. The common line pattern CM mainly includes a wide main portion CM1 that is positioned on the +X side of the individual line pattern B5, and a branch portion CM2 that is branched from the main portion CM1.

In the conductor pattern 23b, the individual line patterns G1 to G8, R1 to R8, and B1 to B8 are respectively connected to the point light sources G21 to G28 that are arranged along a straight line L1 parallel to the Y axis, the individual line patterns G1 to G4, R1 to R4, and B1 to B4 are drawn around on the −X side of the straight line L1, and the individual line patterns G5 to G8, R5 to R8, and B5 to B8 are drawn around on the +X side of the straight line L1. Then, the branch portion CM2 is arranged to be interposed between the individual line patterns G1 to G4, R1 to R4, and B1 to B4 and the individual line patterns G5 to G8, R5 to R8, and B5 to B8.

In addition, the dummy line patterns D1 and D2 are formed in a region in which the individual line pattern and the common line pattern are not arranged.

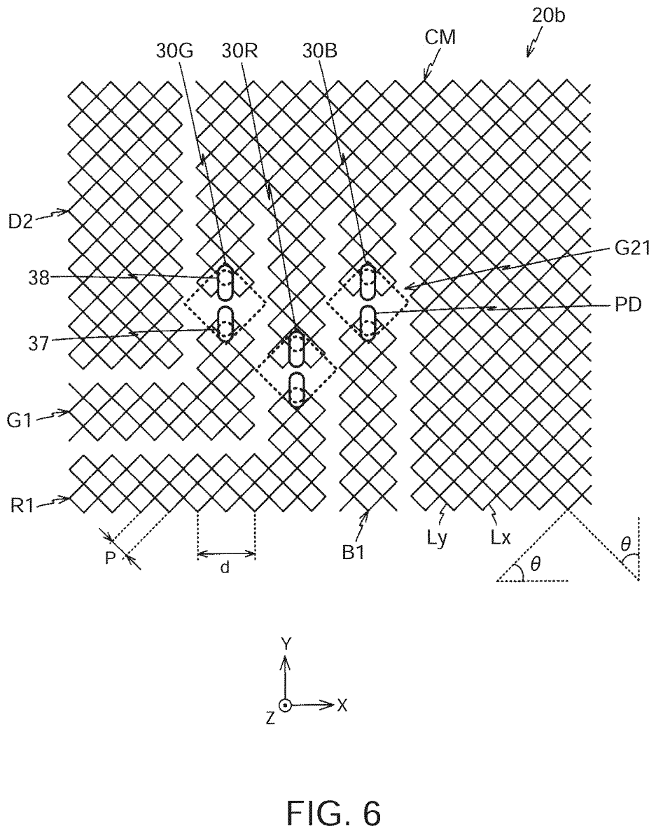

The individual line patterns G1 to G8, R1 to R8, and B1 to B8, the common line pattern CM, and the dummy line patterns D1 and D2 are formed of a mesh pattern. FIG. 6 is a diagram enlargedly illustrating the vicinity of the point light source G21. As known with reference to FIG. 6, the individual line patterns G1, R1, and B1, the common line pattern CM, and the dummy line pattern D2 include a line Lx having an angle of 45 degrees with respect to the X axis, and a line Ly having an angle of 45 degrees with respect to the Y axis.

In the lines Lx and Ly, a line width is approximately 5 μm. In addition, an array pitch P of the lines Lx and Ly is approximately 150 μm. In the individual line patterns G1, R1, and B1, and the common line pattern CM, a connection pad PD to which the bumps 37 and 38 of the light emitting elements 30R, 30G, and 30B are connected is formed. In the light emitting elements 30R, 30G, and 30B, the bumps 37 and 38 are connected to the connection pad PD, and thus, the light emitting elements 30R, 30G, and 30B are electrically connected to the individual line patterns G1, R1, and B1, and the common line pattern CM.

As with the conductor pattern 23b described above, the conductor patterns 23a, and 23c to 23h illustrated in FIG. 1 also include 24 individual line patterns G1 to G8, R1 to R8, and B1 to B8, the common line pattern CM, and two dummy line patterns D1 and D2.

Returning to FIG. 4, the resin layer 24 is an insulator that is formed between the substrate 21 and the substrate 22. The resin layer 24, for example, is formed of a thermosetting resin or a thermoplastic resin having translucency. An epoxy-based resin, an acrylic resin, a styrene-based resin, an ester-based resin, a urethane-based resin, a melamine resin, a phenolic resin, an unsaturated polyester resin, a diallyl phthalate resin, and the like are known as the thermosetting resin. A polypropylene resin, a polyethylene resin, a polyvinyl chloride resin, an acrylic resin, a Teflon (Registered Trademark) resin, a polycarbonate resin, an acrylonitrilebutadiene styrene resin, a polyamide imide resin, and the like are known as the thermoplastic resin. Among them, the epoxy-based resin is excellent in fluidity at the time of softening, adhesiveness after hardening, weather resistance, and the like, in addition to translucency, electric insulating, flexibility, and the like, and thus, is preferable as a configuration material of the resin layer 24.

As illustrated in FIG. 4, in the light emitting panel 20 configured as described above, the length of the substrate 22 in the Y axis direction is shorter that of the substrate 21. For this reason, the conductor layer 23 is in a state where an end portion on the −Y side is exposed.

A flexible cable 402 is a wiring substrate having flexibility in which the longitudinal direction is set to the Y axis direction. As illustrated in FIG. 1, the flexible cable 402 is formed into a tapered shape in which a width (a dimension in the X axis direction) decreases from an end on the +Y side towards an end on the −Y side.

As illustrated in FIG. 4, the flexible cable 402, for example, is formed of a material such as polyimide, and includes a base substrate 40 having insulating properties and flexibility, a conductor pattern 41 that is connected to the conductor layer 23 of the light emitting panel 20, and a coverlay 42 that covers the conductor pattern 41. The conductor pattern 41 covered with the coverlay 42 is in a state where only both end portions in the Y axis direction are exposed. The conductor pattern 41 includes a plurality of lines. Such lines will be described below.

As illustrated in FIG. 4, in the flexible cable 402, a lower surface in an end portion of the base substrate 40 on the +Y side adheres to an upper surface in an end portion of the substrate 21 on the −Y side configuring the light emitting panel 20, by an anisotropically conductive adhesive agent. As illustrated in FIG. 1, the flexible cable 402 adheres to the light emitting panel 20 such that the conductor pattern 23b of the light emitting panel 20 overlaps with the flexible cable 402.

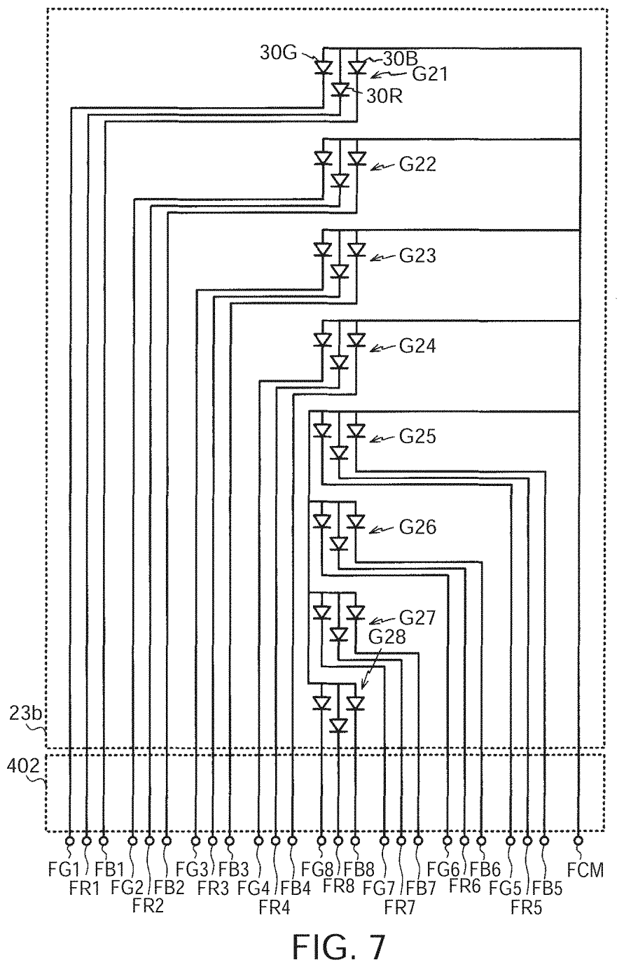

FIG. 7 is a diagram illustrating a circuit that is formed by allowing the flexible cable 402 to adhere to the light emitting panel 20. As illustrated in FIG. 7, 25 lines FG1 to FG8, FR1 to FR8, FB1 to FB8, and FCM are formed in the flexible cable 402. Each of the lines FG1 to FG8, FR1 to FR8, and FB1 to FB8 of the flexible cable 402 is connected to the cathode of the light emitting elements 30G, 30R, and 30B configuring the point light sources G21 to G28. In addition, the line FCM of the flexible cable 402 is connected to all of the anodes of the light emitting elements 30G, 30R, and 30B configuring the point light sources G21 to G28.

The flexible cables 401, and 403 to 408 have the same configuration as that of the flexible cable 402 described above. As illustrated in FIG. 1, each of the flexible cables 401, and 403 to 408 adheres to the light emitting panel 20 such that the conductor patterns 23a, and 23c to 23h of the light emitting panel 20 overlap with the flexible cables 401, and 403 to 408.

In the light emitting device 10 configured as described above, a voltage is selectively applied between the lines FG1 to FG8, FR1 to FR8, and FB1 to FB8 of the flexible cables 401 to 408, and the line FCM, and thus, it is possible to individual turn on the light emitting elements 30R, 30G, and 30B configuring the point light source Gmn.

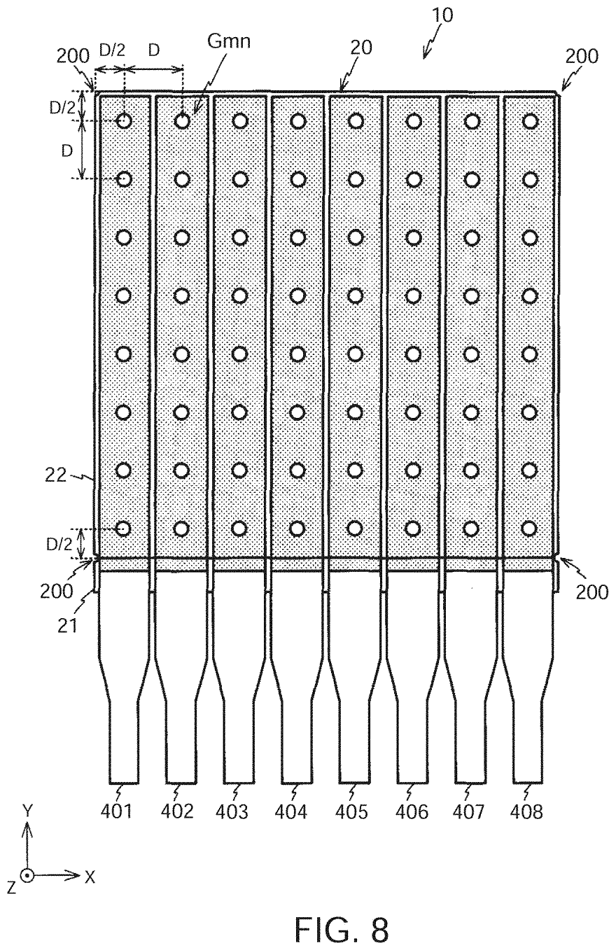

FIG. 8 is a diagram for illustrating an array of the point light sources Gmn. As illustrated in FIG. 8, in the light emitting device 10, a circular notch 200 is provided in a corner portion of the substrate 22. In addition, each of the point light sources Gmn is arrayed such that an array pitch in the X axis direction and the Y axis direction is D, and a distance from an outer edge of the substrate 22 configuring the light emitting panel 20 to the closest point light source Gmn is D/2. Specifically, the array pitch D is greater than or equal to 0.3 cm and less than or equal to 3.2 cm.

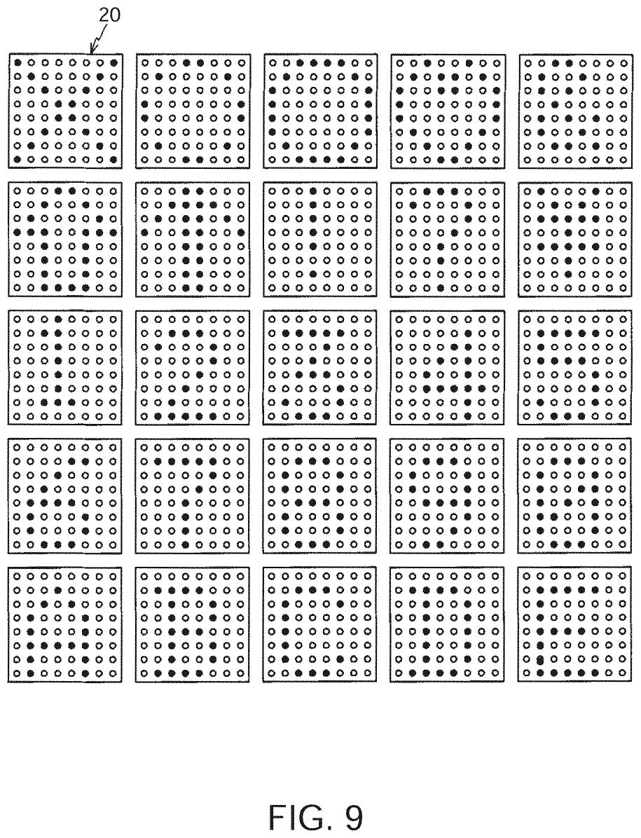

FIG. 9 is a diagram illustrating a text that is displayed on the light emitting panel 20. In the light emitting device 10, the point light source Gmn of the light emitting panel 20 is selectively turned on, and thus, it is possible to display various patterns.

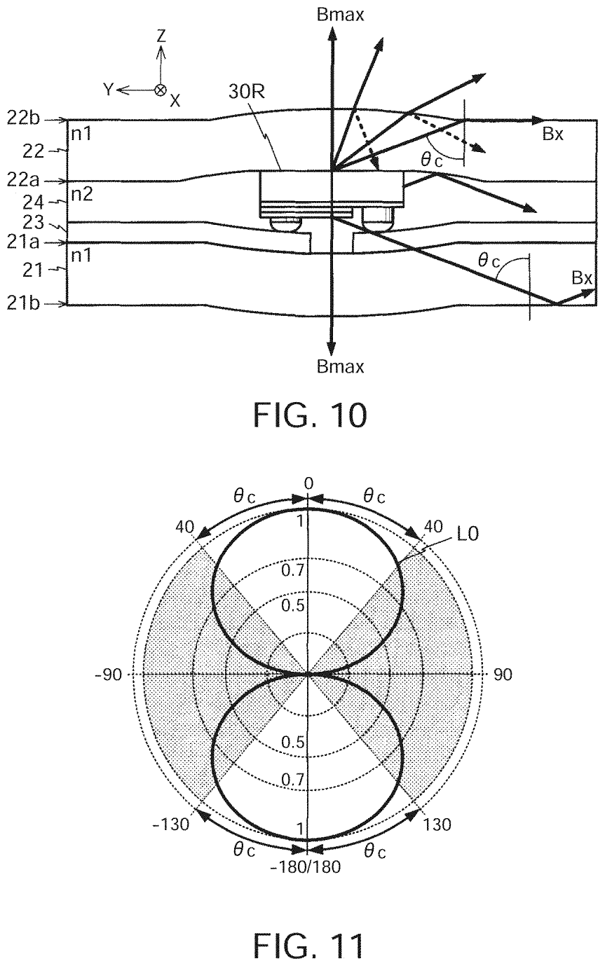

FIG. 10 is a diagram schematically illustrating radiant light exiting from the light emitting elements 30R, 30G, and 30B by using an arrow. As known with reference to FIG. 10, in the radiant light that exits from the light emitting elements 30R, 30G, and 30B, and then, is incident on second surfaces 21b and 22b of the substrates 21 and 22 through first surfaces 21a and 22a of the substrates 21 and 22, incident light Bx that is incident on the second surfaces 21b and 22b of the substrates 21 and 22 at a critical angle θc does not exit from the second surfaces 21b and 22b to the outside.

The substrates 21 and 22 are formed of PET. For this reason, a refractive index of the substrates 21 and 22 is approximately 1.655. When the refractive index is 1.6, the critical angle θc is 39 degrees, and when the refractive index is 1.7, the critical angle θc is 36 degrees. The substrates 21 and 22 are formed of PET, and thus, the refractive index of the substrates 21 and 22 is approximately 1.655. Therefore, in the substrates 21 and 22, the critical angle θc is approximately 40 degrees.

Furthermore, the critical angle θc in the second surfaces 21b and 22b of the substrates 21 and 22 is obtained by Expression (1) described below using a refractive index n1 of the substrates 21 and 22.

Sin θc=1/n1 (1)

The substrates 21 and 22, for example, are also formed of acryl, polycarbonate, and epoxy. A refractive index of each of the materials described above is 1.5, 1.586, and 1.55 to 1.61. For this reason, the critical angle θc in the substrates 21 and 22 is approximately 40 degrees.

FIG. 11 is a diagram illustrating a light distribution curve L0 of the light emitting element 30R that is used in the light emitting device 10. The light distribution curve L0 represents a light distribution of light exiting from the light emitting element 30R. In addition, the light distribution curve L0 represents the intensity of the radiant light that is radiated in each direction by setting the value of the most intensive radiant light Bmax to a peak value, and by setting the peak value to 1. The light distribution curve L0 of a colored region illustrated in FIG. 11 represents the intensity of light that penetrates through the substrates 21 and 22 without being emitted from the substrates 21 and 22 to the outside. In addition, the light distribution curve L0 of the other region represents the intensity of light that is radiated from the second surfaces 21b and 22b of the substrates 21 and 22 to the outside.

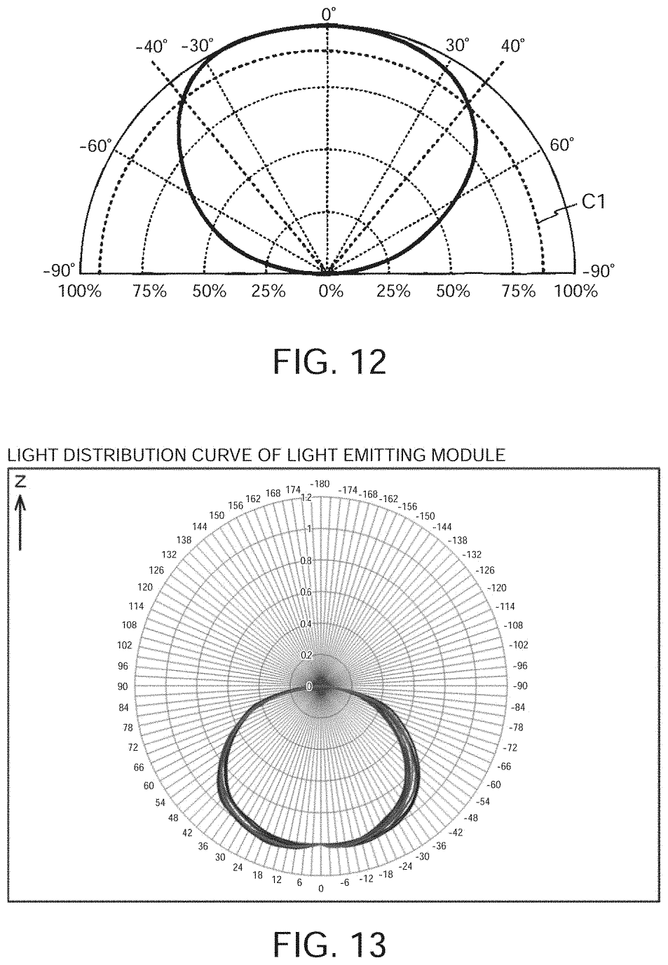

FIG. 12 illustrates an actual light distribution curve of the light emitting elements 30R, 30G, and 30B. In the surface of the light emitting device 10 on a +Z side, in a case where a direction orthogonal to the second surfaces 21b and 22b of the substrates 21 and 22 is set to 0°, light that exits in a direction of 0° to 40° or 0° to −40° in FIG. 12 is the radiant light that is radiated from the substrates 21 and 22 to the outside, and light from 40° to 90° or −40° to −90° is guided light that propagates through the substrates 21 and 22. That is, in the light from the light emitting element 30R, light of which an incident angle is 40° to 90° or −40° to −90° is prevented from being radiated from the substrates 21 and 22.

A semicircle C1 illustrated in FIG. 12 represents a position of a relative intensity of 0.9. In a position of 40° and −40°, the light distribution curve intersects with the semicircle C1. Therefore, a relative intensity of light that exits in a direction of 40° and −40° is approximately 0.9. For this reason, in the light emitting device 10, only light of which the relative intensity is greater than or equal to 0.9 is radiated to the outside, and light of which the relative intensity is less than 0.9 is guided to the substrates 21 and 22 and the like. That is, in the light emitting device 10, light from the light emitting element is filtered, and only light of which the intensity is comparatively strong is radiated to the outside.

FIG. 13 illustrates a light distribution curve of the light emitting element 30R of the light emitting device 10. In the light emitting device 10, the light from the light emitting element is filtered, and only the light of which the intensity is comparatively strong is radiated to the outside. For this reason, the light distribution curve is approximately circular. For this reason, as illustrated in FIG. 46, it is possible to recognize each of the point light sources Gmn as the point light source.

The inventors or the like examine a condition in which when the light emitting device 10 is obliquely seen, the point light source Gmn of the light emitting device 10 is sufficiently recognized as the point light source. As described by using FIG. 10, a part of light exiting from the light emitting element 30R propagates through the substrates 21 and 22 or the resin layer 24 without exiting to the outside of the substrates 21 and 22. For this reason, the intensity of the light exiting to the outside being high is the condition in which the point light source Gmn is recognized as the point light source even in a case where the light emitting device 10 is seen from all directions including when the light emitting device 10 is obliquely seen. In this case, it is known that in light distribution properties of the light emitting element, in a case where the angle of the light exiting from the substrates 21 and 22 to the outside, that is, the intensity of light of which an incident angle with respect to the substrates 21 and 22 illustrated in FIG. 11 is less than θc is 1.0 to 0.7, for example, as with a picture of FIG. 46, the point light source Gmn of the light emitting device 10 is sufficiently recognized as the point light source.

In general, when light having different intensities is seen by a person, and a difference in the intensities of the light is greater than 30%, it is possible to recognize the difference in the intensities. However, when the difference in the intensities of the light is less than or equal to 30%, it is not possible to recognize the difference in the intensities. In the light emitting device 10, in a case where the intensity of the light of which the incident angle is less than θc is 1 to 0.7, each of the point light sources Gmn is recognized as the point light source.

In this embodiment, the array pitch D of each of the point light sources Gmn illustrated in FIG. 8 in the X axis direction and the Y axis direction is greater than or equal to 0.3 cm and less than or equal to 3.2 cm. Therefore, it is possible to improve the visibility of the light emitting device, and to improve the visibility of an object through the light emitting device 10 having light transmittivity. Hereinafter, test results thereof will be described.

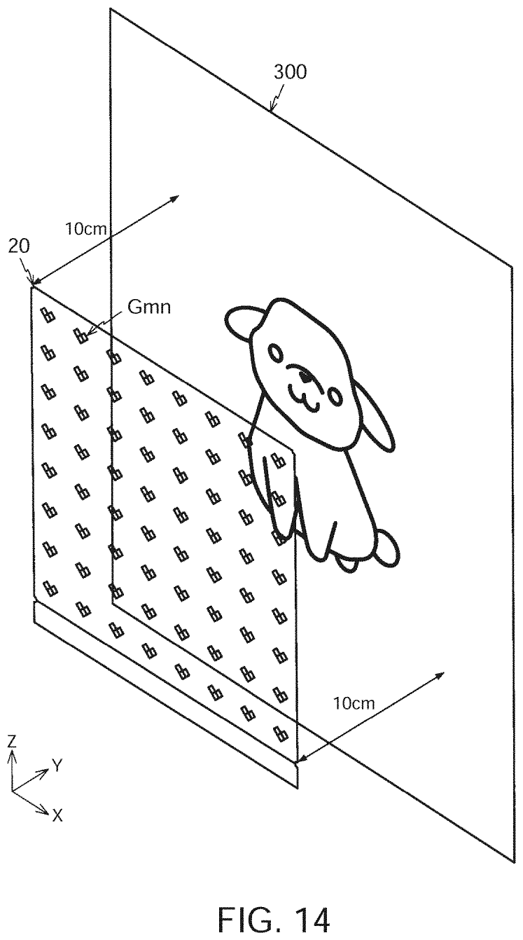

The inventors or the like conduct a test for deriving a condition in which it is possible to identify the object through the light emitting device 10 while recognizing the point light source of the light emitting device 10. In a visibility test, the object is observed through the light emitting panel 20 of the light emitting device 10, and at this time, the visibility of the object is verified. Specifically, as illustrated in FIG. 14, paper 300 of an A4 size on which an illustration is drawn as the object is prepared. Then, the illustration of the paper 300 is observed through the light emitting panel 20 of the light emitting device 10 positioned in a portion that is separated from the paper 300 by 10 cm.

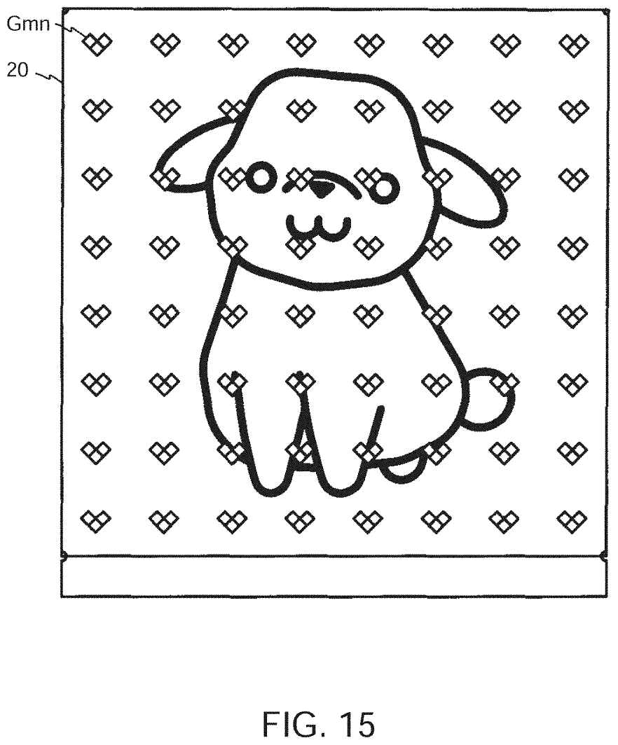

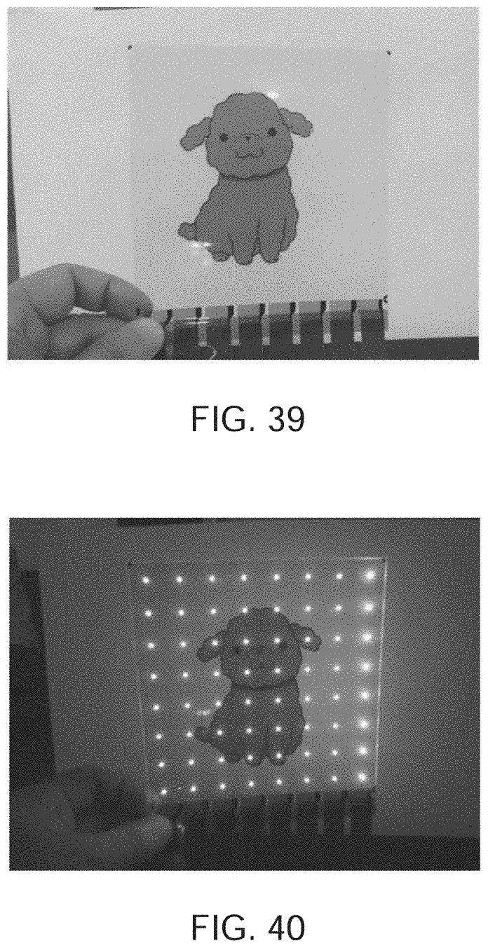

As illustrated in FIG. 15, when the point light source Gmn of the light emitting panel 20 does not emit light, it is possible to visually confirm the illustration of the paper 300 without being affected by the point light source Gmn (for example, refer to a picture of FIG. 39). The picture is obtained by capturing the illustration of the paper 300 under an indoor light.

However, in a case where the light emitting elements 30R, 30G, and 30B configuring the point light source Gmn of the light emitting panel 20 emit light, a part of the light from the light emitting elements 30R, 30G, and 30B, or light that is diffused and reflected on the electrodes 35 and 36 or the bumps 37 and 38 is guided into a substrate or an intermediate resin, and is leaked to the outside. The substrate or the intermediate resin is not completely transparent, and thus, in a case where light is guided into the substrate or the intermediate resin, a portion different from the point light source looks blurred. For this reason, in a case where the object is observed through the light emitting device that is turned on, the object looks blurred. In addition, as known from a comparison between pictures 39 and 40, the visibility of the object is different according to the on and off of the indoor light. The visibility of the object increases as the surroundings of the object becomes brighter.

The inventors and the like prepare the light emitting devices 10 provided with the light emitting panels 20 having different array pitches of the point light sources. Specifically, nine types of light emitting devices 10 are prepared in which the point light sources Gmn are arrayed in an approximately square light emitting panel 20 of which one side is 117 mm at an array pitch of 0.3 cm, 0.8 cm, 1.0 cm, 1.4 cm, 1.6 cm, 2.0 cm, 2.5 cm, 3.2 cm, and 4.0 cm. Then, a color illustration that is printed on the paper 300 of A4 is observed through the light emitting panel 20 of each of the light emitting devices 10, in a state where the point light source Gmn is turned on. A light intensity of the light emitting element configuring the point light source Gmn is 0.1 to 1 [lm].

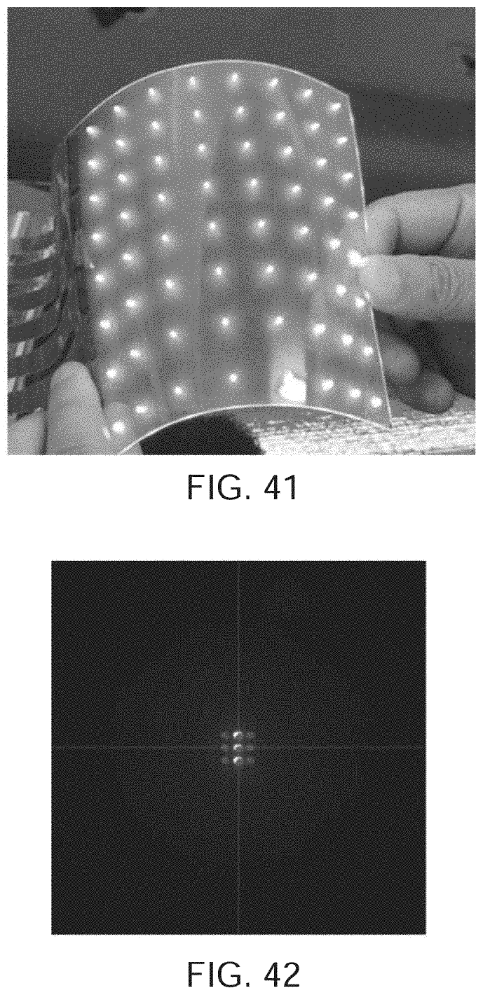

In addition, at this time, the same observation is performed not only in a case where the light emitting panel 20 having flexibility is horizontally maintained, but also in a case where a bus line is bent to be parallel to the Y axis, and to have a radius of 5 cm, 10 cm, and 20 cm, as illustrated in a picture of FIG. 41.

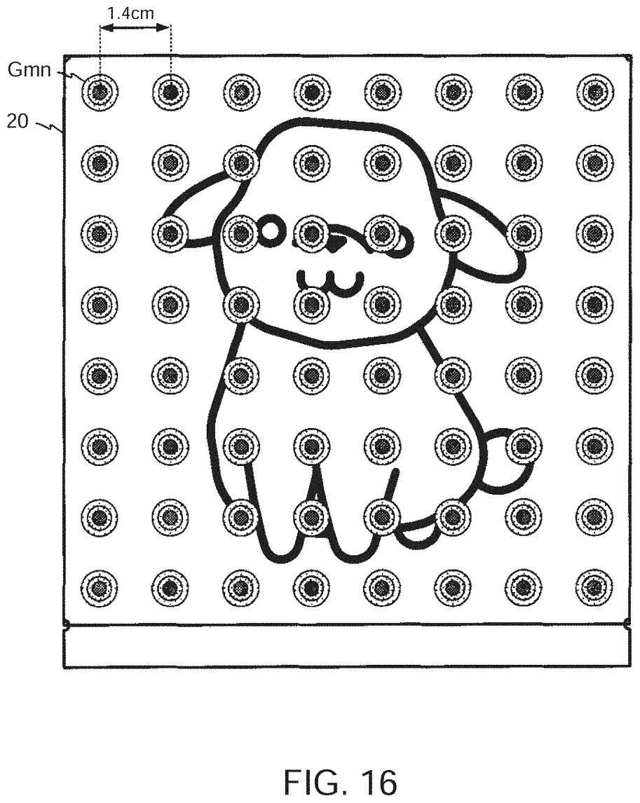

For example, FIG. 16 is an image diagram when the illustration of the paper 300 is observed through the light emitting panel 20 in which the array pitch of the point light sources Gmn is 1.4 cm. As illustrated in FIG. 16, the visibility of the illustration decreases around the point light source Gmn, but it is possible to identify the illustration of the paper 300 as a whole.

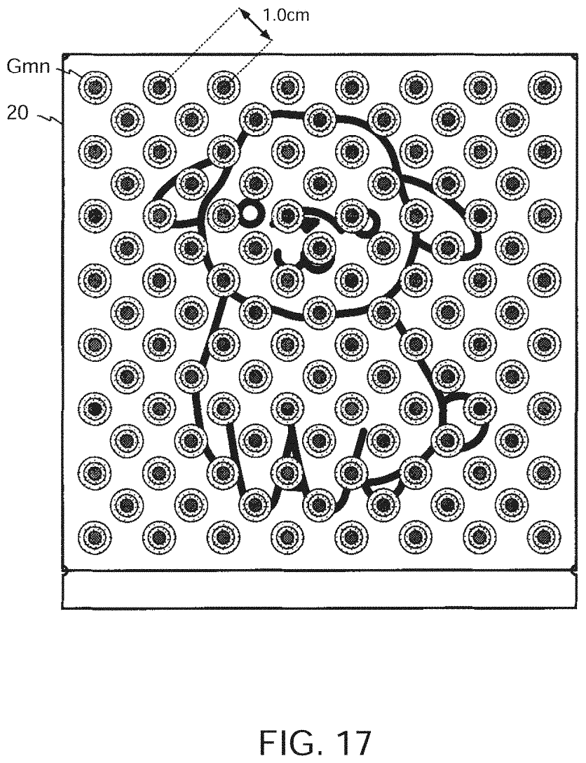

In addition, FIG. 17 is an image diagram when the illustration of the paper 300 is observed through the light emitting panel 20 in which the array pitch of the point light sources Gmn is 1.0 cm. As illustrate din FIG. 21, the visibility of the illustration decreases around the point light source Gmn, and thus, it is slightly difficult to identify the illustration of the paper 300 as a whole.

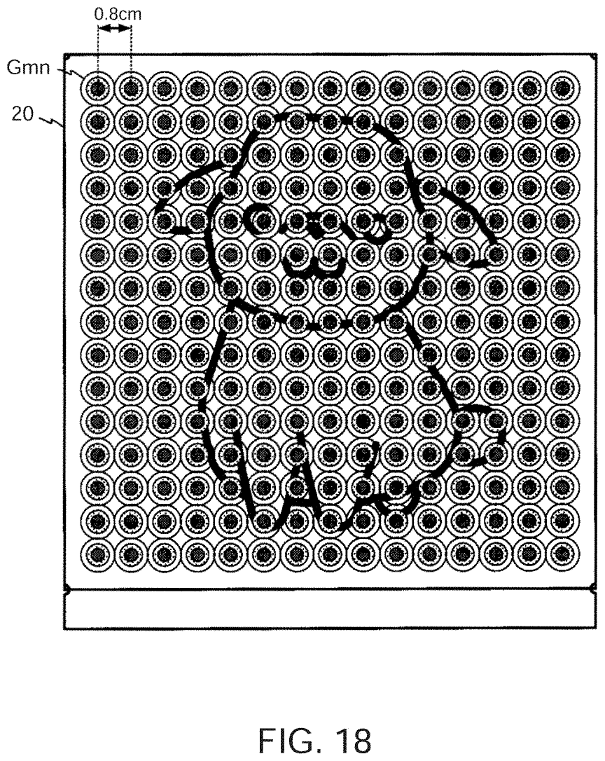

In addition, FIG. 18 is an image diagram when the illustration of the paper 300 is observed through the light emitting panel 20 in which the array pitch of the point light sources Gmn is 0.8 cm. As illustrated in FIG. 18, the visibility of the illustration decreases around the point light source Gmn, and thus, it is difficult to identify the illustration of the paper 300 as a whole.

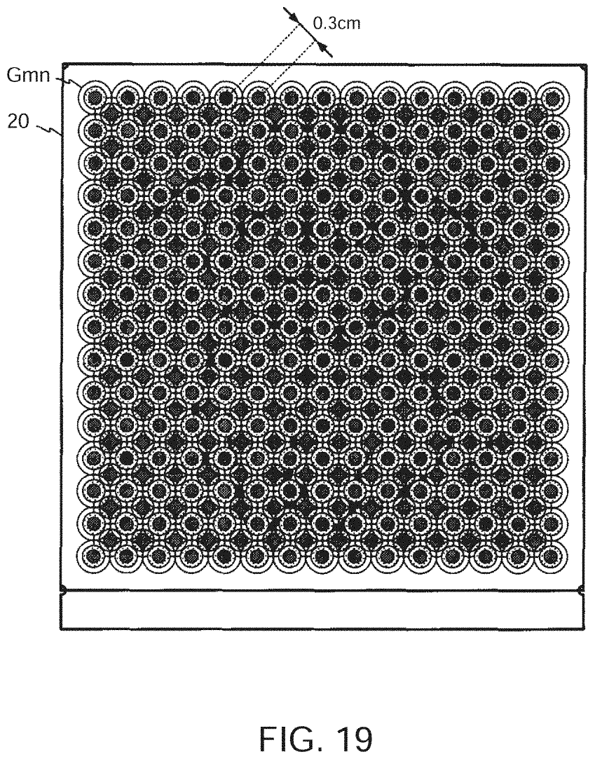

In addition, FIG. 19 is an image diagram when the illustration of the paper 300 is observed through the light emitting panel 20 in which the array pitch of the point light sources Gmn is 0.3 cm. As illustrated in FIG. 19, in a case where the array pitch decreases, the illustration, for example, becomes reddish or looks mottled by the light emitting device 10 according to the color of the light emitted from the point light source. Accordingly, the visibility decreases, and it is considerably difficult to identify the illustration of the paper 300 as a whole.

As described above, the visibility of the illustration of the paper 300 decreases as the array pitch of the point light sources Gmn decreases.

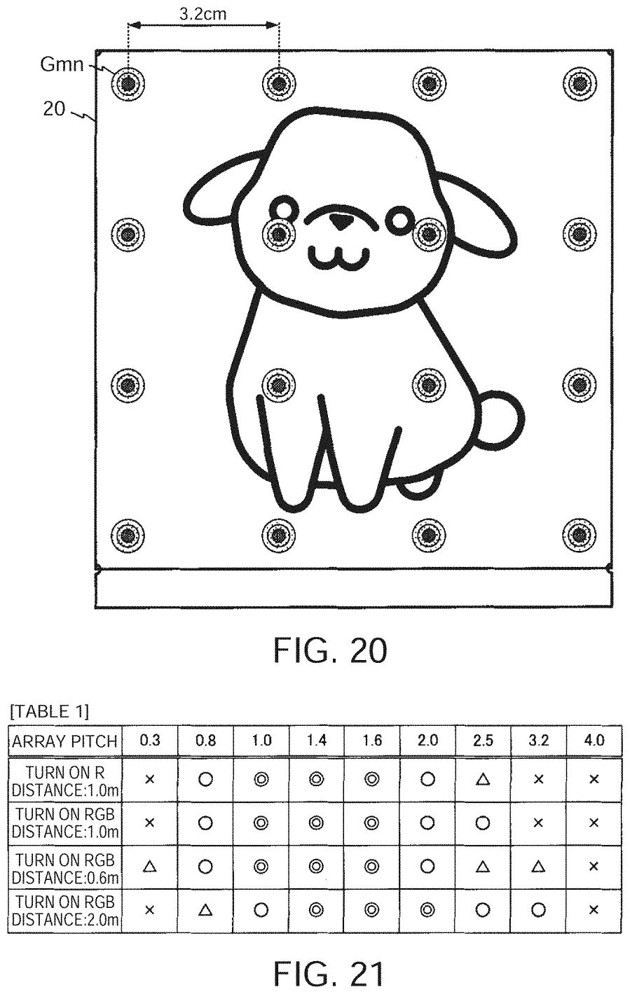

FIG. 20 is an image diagram when the illustration of the paper 300 is observed through the light emitting panel 20 in which the array pitch of the point light sources Gmn is 3.2 cm. As illustrated in FIG. 24, the visibility of the illustration decreases around the point light source Gmn, but there is no influence on identifying the illustration of the paper 300 as a whole.

As described above, in a case where the array pitch of the point light sources Gmn increases, the visibility of the illustration of the paper 300 is not affected by the light emitting panel 20. On the other hand, in this case, display capability or a resolution, and a visual effect of the light emitting panel 20 decrease.

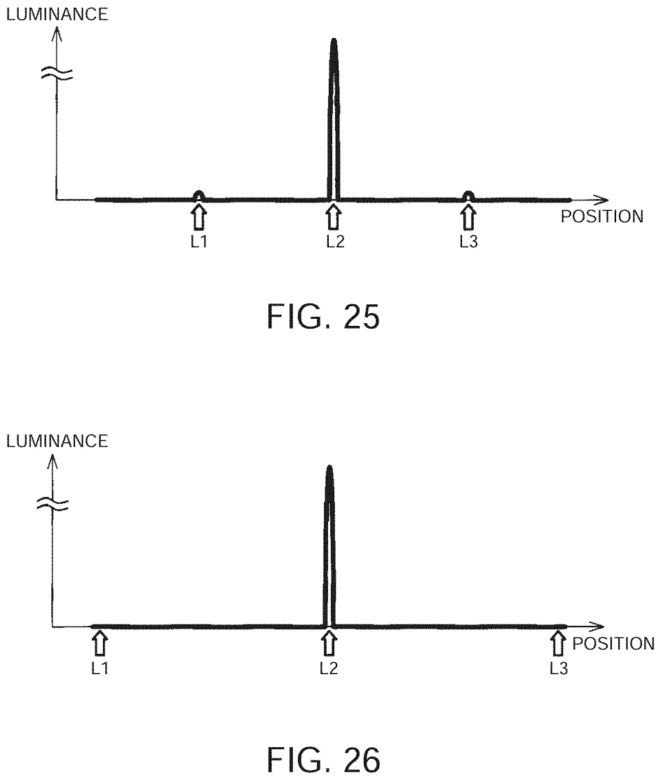

Table 1 of FIG. 25 shows a verification result of the visibility that is obtained by observing the paper 300 through nine types of light emitting panels 20 having different array pitches of the point light sources Gmn. In the verification result, when five observers observe the paper 300 through the light emitting panel, one is selected from four evaluation standards of a state of ⊙ in which the visual effect is most excellent, a state of ◯ in which the visual effect is excellent, a state of Δ in which the visual effect is small, and a state of X in which the visual effect is not exhibited. An observation result is based on the evaluation standards that are selected by four observers in five observers.

In the verification of the light emitting panel 20, in the light emitting elements 30R, 30G, and 30B configuring each of the point light sources Gmn, only the light emitting element 30R is turned on, the illustration of the paper 300 is observed from a position that is separated from the paper 300 by 1.0 m. In addition, all of the light emitting elements 30R, 30G, and 30B are turned on, and the illustration of the paper 300 is observed from each position that is separated from the paper 300 by 1.0 m, 0.6 m, and 2.0 m.

According to Table 1, in a case where the array pitch of the point light sources Gmn is 1.4 cm and 1.6 cm, it is determined that the visual effect is the most excellent in all conditions. In a case where the array pitch is 1.0 cm, it is determined that the visual effect is the most excellent in a plurality of conditions. In a case where the array pitch is 0.8 cm and 2.0 cm, it is determined that the visual effect is excellent in a plurality of conditions. In a case where the array pitch is 2.5, it is determined that the visual effect is excellent in half of the conditions. In a case where the array pitch is 0.3 cm and 3.2 cm, it is determined that the visual effect is not exhibited in most conditions. In a case where the array pitch is 4.0, it is determined that the visual effect is not exhibited in all of the conditions.

As described above, it is preferable that the array pitch of the point light sources Gmn in the light emitting panel 20 is greater than or equal to 0.3 cm and less than or equal to 3.2 cm. In addition, it is more preferable that the array pitch of the point light sources Gmn is greater than or equal to 0.8 cm and less than or equal to 2.5 cm. In addition, it is most preferable that the array pitch of the point light sources Gmn is greater than or equal to 1.4 cm and less than or equal to 1.6 cm.

In the test described above, all of the point light sources Gmn of the light emitting device 10 are turned on. In a case where the light emitting device 10 is actually used, there is a case where a part of the point light sources Gmn is turned on, and the other point light sources Gmn are turned off. In this case, there is a case where the guided light that propagates through the substrates 21 and 22 or the resin layer 24 is reflected on the light emitting element that is turned off, and thus, the light emitting element that is turned off seems to be turned on. In such a state, a fine light emitting pattern is not capable of being realized. Therefore, a test for finding out the array pitch of the point light sources Gmn in which such a phenomenon is suppressed is performed.

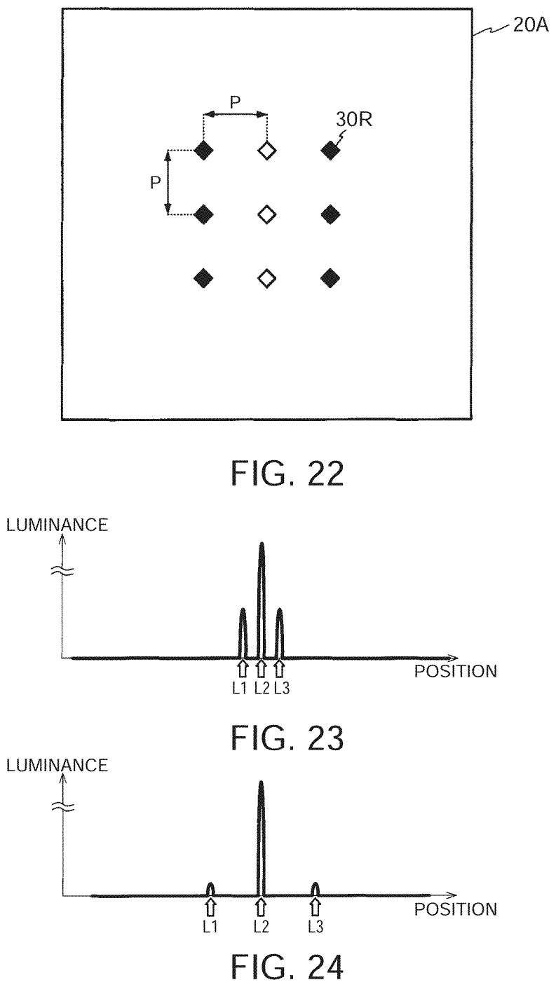

For example, FIG. 22 illustrates a light emitting panel 20A in which the light emitting elements 30R are arranged into the shape of a matrix of three rows and three columns. Four types of light emitting panels 20A are prepared in which the array pitch P of the light emitting element 30R, for example, is 0.9 mm, 3.0 mm, 5.1 mm, and 10.2 mm. Then, in FIG. 22, only three light emitting elements 30R on the second column that are represented by a white square are turned on.

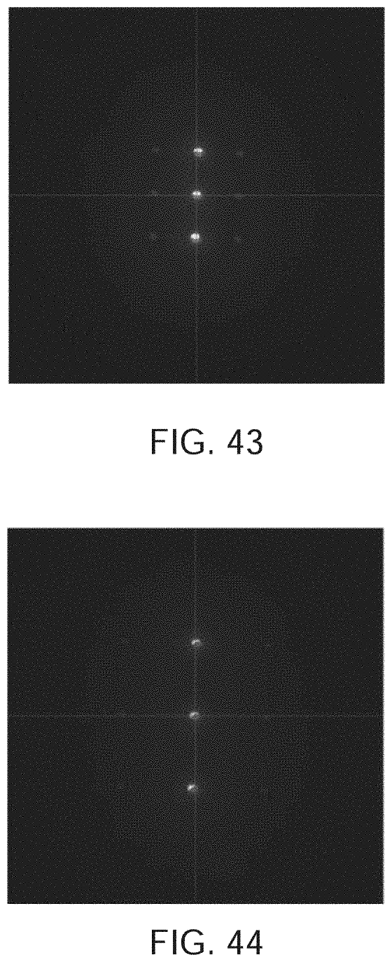

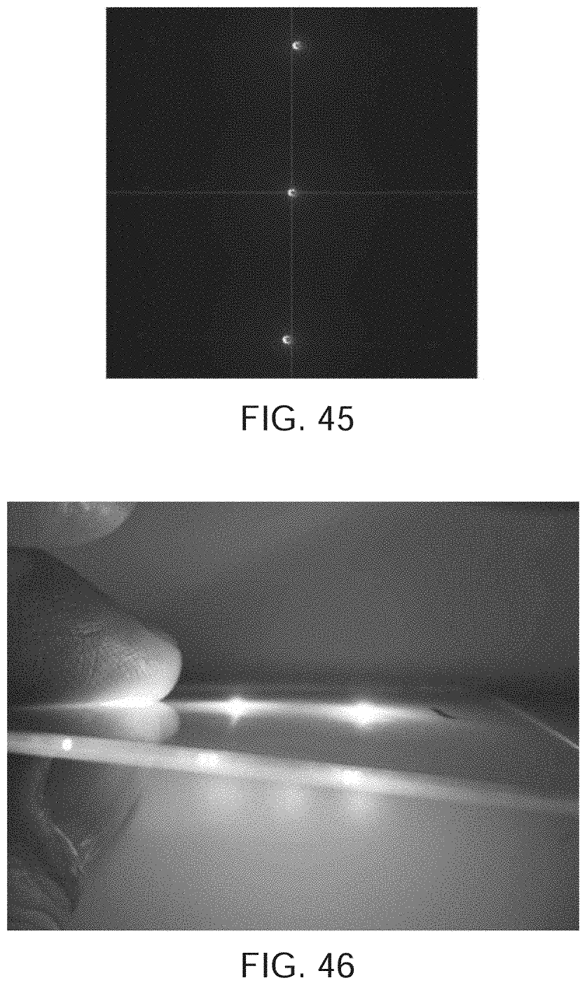

In a case where the array pitch P is 0.9 mm, as illustrated in a picture of FIG. 42, the light emitting elements 30R on the first column and the third column that are adjacent to each other are illuminated by the guided light that is guided from the light emitting element 30R on the second column through the substrates 21 and 22 or the resin layer 24. In this case, the guided light is emitted from the illuminated light emitting element 30R to the outside, and the light emitting element 30R that is turned off seems to emit light. In a case where the array pitch P is 3.0 mm, as illustrated in a picture of FIG. 43, the light emitting elements 30R on the first column and the third column that are adjacent to each other are illuminated by the guided light from the light emitting element 30R on the second column, and similarly, seems to emit light. On the other hand, in a case where the array pitch P is 5.1 mm, the light emitting elements 30R on the first column and the third column that are adjacent to each other are affected by the guided light from the light emitting element 30R on the second column, but as illustrated in a picture of FIG. 44, do not particularly stand out. In addition, in a case where the array pitch P is 10.2 mm, the light emitting elements 30R on the first column and the third column that are adjacent to each other are rarely affected by the guided light from the light emitting element 30R on the second column, and as illustrated in a picture of FIG. 45, rarely stand out.

FIG. 23 to FIG. 26 are diagrams illustrating a graph in which results illustrated in the pictures of FIG. 42 to FIG. 45 are digitized. A vertical axis represents a luminance, and a horizontal axis represents the position of the light emitting elements 30R on the first column L1 to the third column L3. As illustrated in FIG. 23, in a case where the array pitch P is 0.9 mm, a large peak representing the luminance of the light emitting elements on the first column L1 and the third column L3 appears. The peak representing the luminance of the light emitting elements on the first column L1 and the third column L3 in a case where the array pitch P is 3.0 mm, as illustrated in FIG. 24, and in a case where the array pitch P is 5.1 mm, as illustrated in FIG. 25 is considerably smaller than a peak in a case where the array pitch P is 0.9 mm. In addition, as illustrated in FIG. 26, the peak representing the luminance on the first column L1 and the third column L3 in a case where the array pitch P is 5.1 mm is rarely observed. As described above, in a case where the array pitch of the light emitting elements increases, the intensity of the guided light that reaches the light emitting element that is turned off decreases, and thus, the light emitting element that is turned off is not visually confirmed as being bright.

Therefore, the light emitting elements on the first column L1 and the third column L3 that are affected by the light emitting element 30 on the second column L2 that emits light are visually confirmed as illustrated in the pictures of FIG. 42 to FIG. 45. For this reason, it is preferable that the array pitch of the light emitting elements configuring the point light source is greater than or equal to 5 mm, and it is more preferable that the array pitch is greater than or equal to 10 mm. In addition, as illustrated in the picture of FIG. 45, in a case where the array pitch of the light emitting elements is greater than or equal to 10.2 mm, it is obvious that the light emitting element is not affected by light from the adjacent light emitting element. For this reason, it is most preferable that the array pitch of the light emitting elements configuring the point light source is greater than or equal to 10.2 mm.

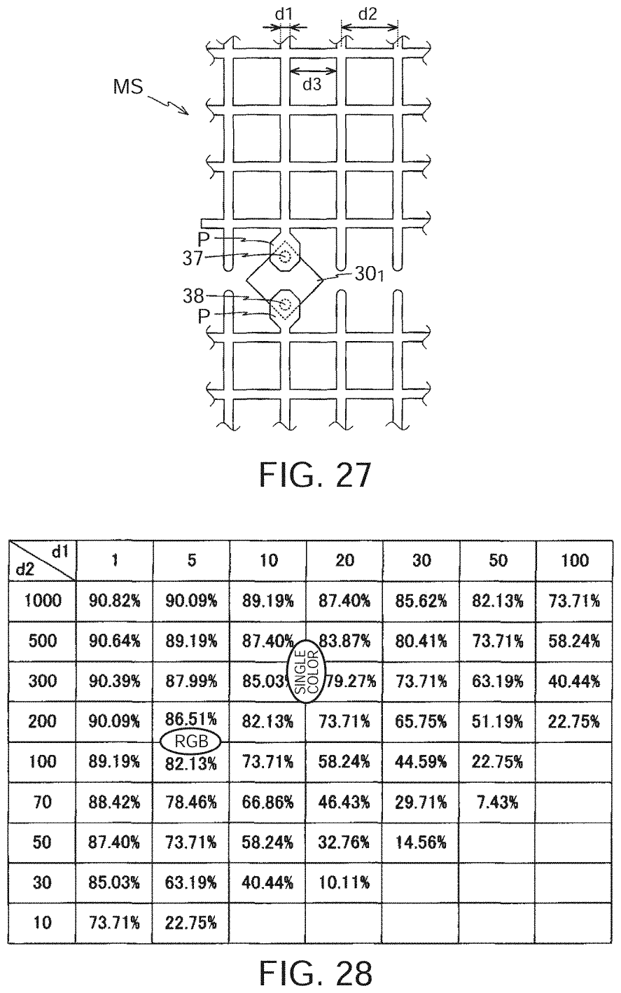

In the transparence of the resin layer 24, a relationship between the condition of a mesh pattern configuring the conductor layer 23, and the array pitch of the light emitting element is considered. FIG. 27 is a diagram illustrating a mesh pattern MS. In a line pattern of the mesh pattern MS, a line width is d1, and an array pitch is d2. FIG. 28 shows a marginal transparency of a panel only including a mesh pattern that is formed of copper, and a substrate that is formed of PET and has a thickness of 100 μm.

In the light emitting device 10, in a case where the point light source Gmn includes one light emitting element, the line width d1 is 15 μm, and the pitch d2 is 300 μm. In this case, with reference to FIG. 28, it can be expected that the transmittance is approximately 82%. In addition, in a case where the point light source Gmn includes three light emitting elements, the line width d1 is 5 μm, and the pitch d2 is 150 μm. In this case, with reference to FIG. 28, it can be expected that the transmittance is approximately 84%. However, in an actual product of the light emitting device 10, the transmittance is greater than 80%, and thus, there is a difference of approximately several %. Such a difference is due to the number of light emitting elements, and the number of light emitting elements per unit area increases proportionately as the array pitch of the light emitting elements decreases.

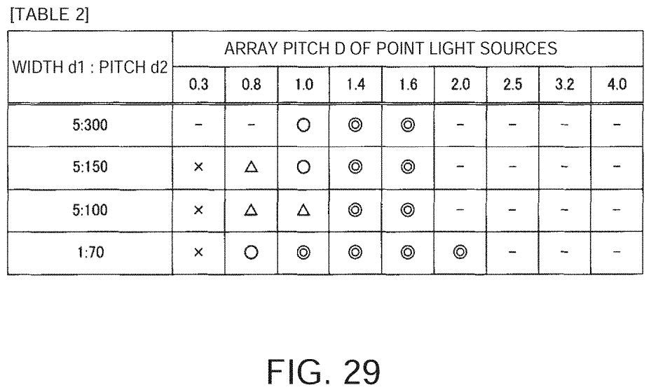

FIG. 29 illustrates Table 2 showing a consideration result. In the result of Table 2, a case where the light emitting panel 20 is observed from a position separated by 30 cm, and is determined as being sufficiently transparent is set to ⊙, a case where the light emitting panel 20 is determined as being attractive as a transparent product is set to ◯, a case where the light emitting panel 20 is determined as being slightly degraded as the transparent product is set to Δ, and a case where the light emitting panel 20 is determined as being semi-transparent is set to x. From the result of Table 2, it is known that the transparence of the light emitting device 10 is most sufficient when a relationship (D, d1:d2) between the array pitch D of the point light sources Gmn, and Line Width d1: Pitch d2 of the line pattern configuring the mesh pattern is (1.4, 5:300), (1.4, 5:150), (1.4, 5:100), (1.4, 1:70), (1.6, 5:300), (1.6, 5:150), (1.6, 5:100), and (1.6, 1:70).

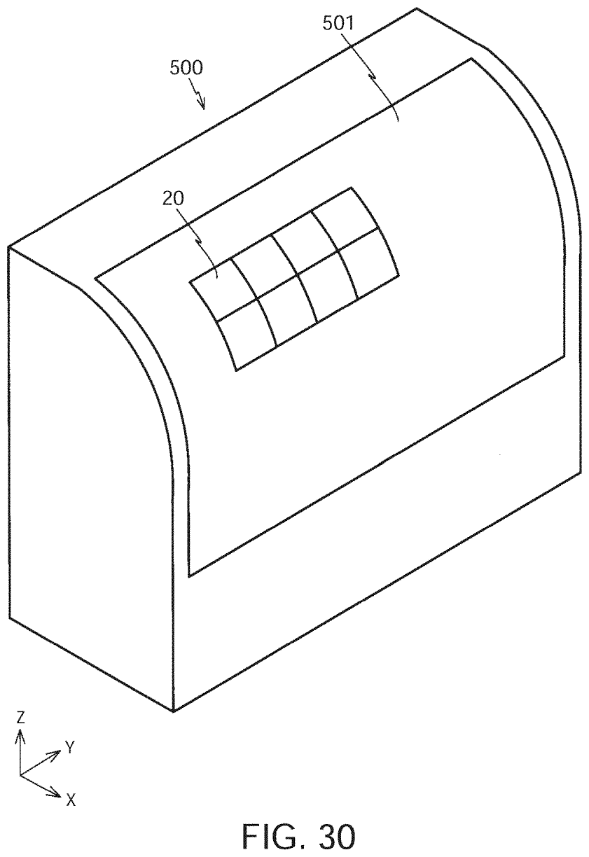

The light emitting device 10 according to this embodiment has flexibility. For this reason, for example, as illustrated in FIG. 30, the light emitting device 10 can be used in a decoration such as a showcase 500 that displays a product or the like through curved glass 501. Even in a case where the light emitting panel 20 is arranged on the curved glass 501, it is possible to display the product through the light emitting panel 20. For this reason, it is possible to display a message by using the light emitting panel 20 without impairing the display of the product. A plurality of light emitting panels 20 are arranged in parallel, and thus, it is possible to perform the display according to the size of the showcase 500. The light emitting device 10 can be used not only as the decoration such as a showcase or a shop window, but also as various decorations or messengers.

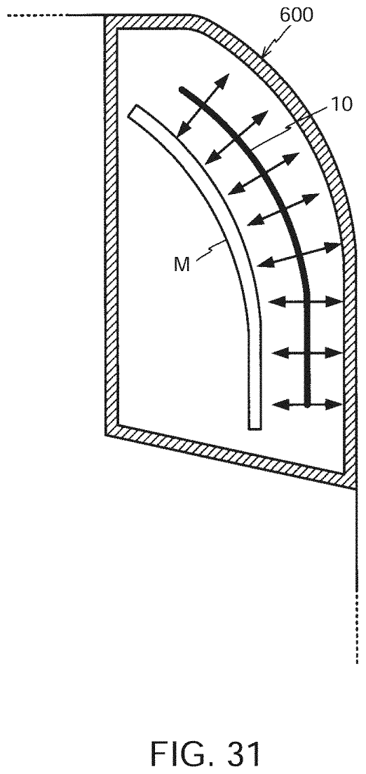

In addition, the light emitting device 10 according to this embodiment can be used in a tail lamp of an automobile. The light emitting panel 20 having translucency and flexibility is used as a light source, and thus, it is possible to realize various visual effects. FIG. 31 is a diagram schematically illustrating a sectional surface of a resin housing on a horizontal surface and an internal structure in a tail lamp 600 of an automobile. The light emitting device 10 is arranged along an inner surface of the resin housing of the tail lamp 600, and a mirror M is arranged on a back surface of the light emitting device 10, and thus, light that exits from the light emitting device 10 to the mirror is reflected on the mirror M, and then, is transmitted through the light emitting panel 20, and exits to the outside. Accordingly, a unit can be formed in which it seems that there is a light source different from the light emitting device 10 in a depth direction of the tail lamp 600.

In the light emitting device 10 according to this embodiment, the light emitting elements 30R, 30G, and 30B or the conductor layer 23 are watertight by the resin layer 24. For this reason, the light emitting device 10 can be arranged in water.

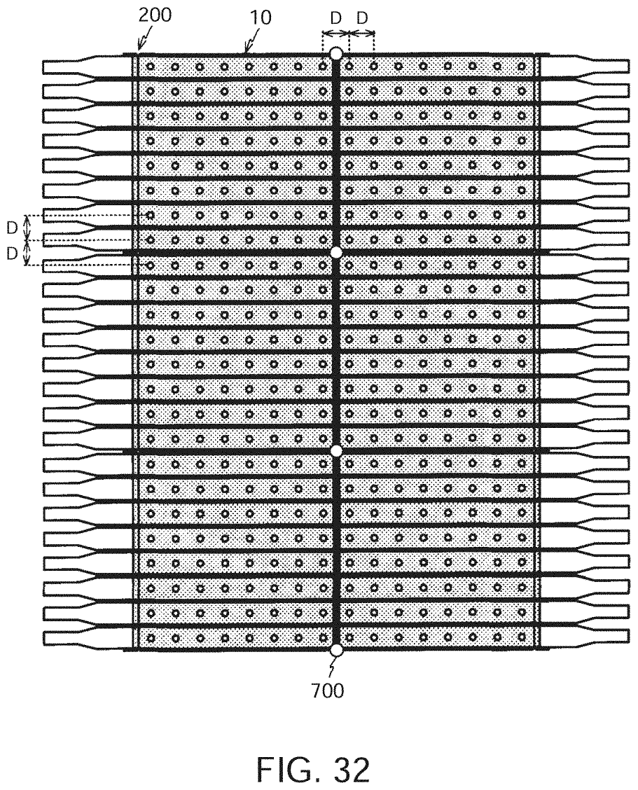

In the light emitting panel 20 according to this embodiment, as illustrated in FIG. 8, each of the point light sources Gmn is arrayed such that the array pitch in the X axis direction and the Y axis direction is D, and the distance from the outer edge of the substrate 22 configuring the light emitting panel 20 to the closest point light source Gmn is D/2. Therefore, for example, as illustrated in FIG. 32, even in a case where a plurality of light emitting devices 10 are arranged such that the light emitting panels 20 are adjacent to each other, the array pitch of the point light sources Gmn between the light emitting devices 10 is D. Accordingly, the light emitting devices 10 are freely combined, and it is possible to expand the application of the light emitting device 10 or to improve the expressivity of the light emitting device 10.

In the light emitting panel 20 according to this embodiment, four circular notches 200 are provided. For this reason, as illustrated in FIG. 32, in a case where the plurality of light emitting devices 10 are arranged such that the light emitting panels 20 are adjacent to each other, a screw 700 is inserted into an opening or a semicircular notch that is formed by the notch 200, and thus, it is possible to fix each of the light emitting devices 10 to the object by using a screw or a washer. In addition, the notch 200 can be used as a standard position at the time of positioning the light emitting panel 20.

In this embodiment, the light emitting elements 30R, 30G, and 30B are connected to each other by 24 individual line patterns G1 to G8, R1 to R8, and B1 to B8, and the common line pattern CM that are formed of the mesh pattern. The mesh pattern described above is configured of a metal thin film having a line width of approximately 5 For this reason, it is possible to sufficiently ensure the transparence and the flexibility of the light emitting device 10.

In this embodiment, in the set of substrates 21 and 22, the conductor layer 23 including the conductor patterns 23a to 23h is formed on the upper surface of the substrate 21. For this reason, the light emitting device 10 according to this embodiment is thin compared to a light emitting device in which the conductor layer is formed on both of the upper surface and the lower surface of the light emitting elements 30R, 30G, and 30B. As a result thereof, it is possible to improve the flexibility and the transparency of the light emitting device 10.

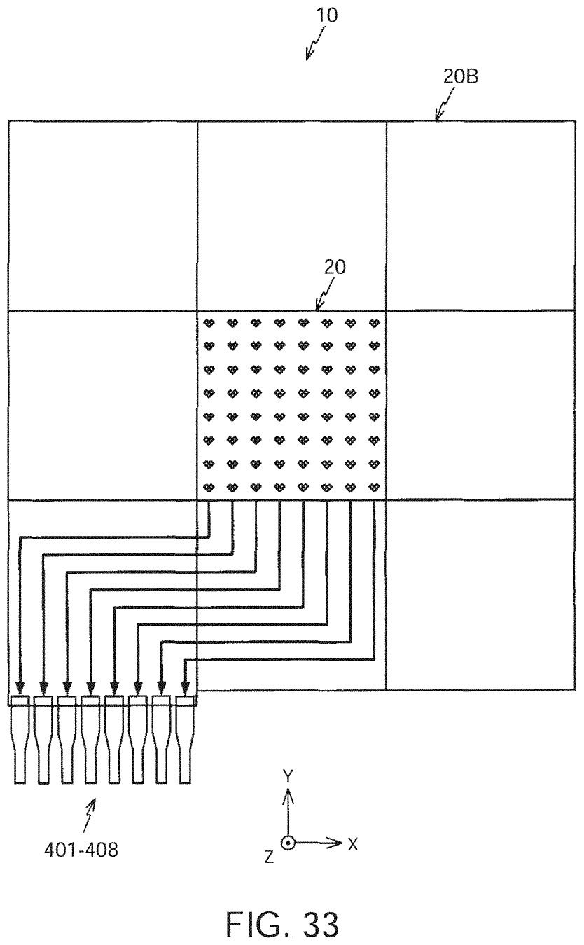

The embodiment of the invention is described above, but the invention is not limited to the embodiment described above. For example, in the embodiment described above, a case is described in which the flexible cables 401 to 408 are directly connected to the light emitting panel 20 including the point light source Gmn. The invention is not limited thereto, and as illustrated in FIG. 33, the flexible cables 401 to 408 may be connected to the light emitting panel 20 through a panel 20B. The panel 20B includes the substrates 21 and 22, the conductor layer 23, and the resin layer 24. The panel 20B has a configuration equivalent to that of the light emitting panel 20 except that the light emitting element is not provided.

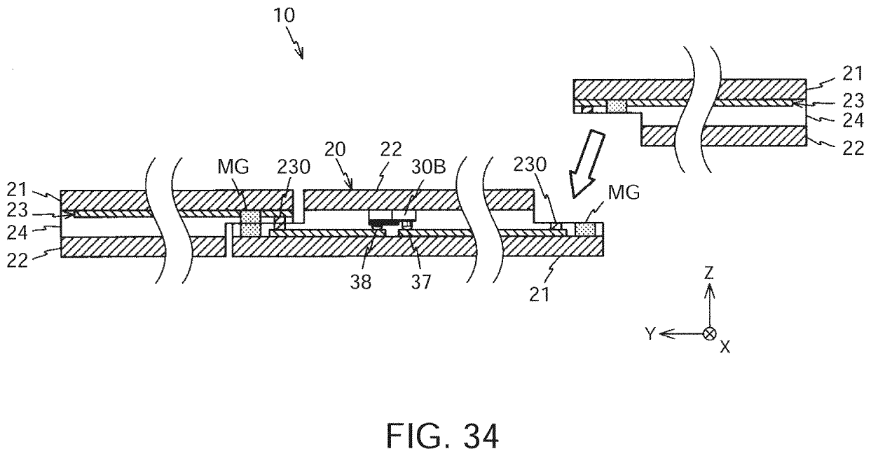

FIG. 34 is a diagram illustrating a YZ sectional surface of the light emitting device 10 according to a modification example described above. In the light emitting panel 20, the resin layer 24 is exposed from an outer edge portion. Then, a via conductor 230 that is connected to the conductor layer 23, and a connection pad MG formed of a magnet are exposed to the exposed resin layer 24. The via conductor 230 is provided for each of 24 individual line patterns G1 to G8, R1 to R8, and B1 to B8, and the common line pattern CM configuring the conductor layer 23. The connection pad MG, for example, is provided on four corners of the substrate 21, and the like.

As illustrated in FIG. 34, the connection pad MG on the outer edge of the light emitting panel 20 adheres to the connection pad MG of the panel 20B, and thus, as illustrated in FIG. 33, the light emitting panel 20 and the panel 20B can be combined. The light emitting elements 30R, 30G, and 30B of the light emitting panel 20 are respectively connected to the lines FG1 to FG8, FR1 to FR8, FB1 to FB8, and FCM of the corresponding flexible cables 401 to 408 through the conductor layer 23 of the panel 20B.

In addition, the conductor layers 23 of the light emitting panel 20 and the panel 20B may adhere to each other, for example, by using an anisotropically conductive adhesive agent instead of the connection pad MG.

In the light emitting device 10 according to modification example, for example, in a case where the light emitting panel 20 is provided on glass or the like, it is possible to perform wiring from each of the light emitting elements without impairing the translucency of the glass.

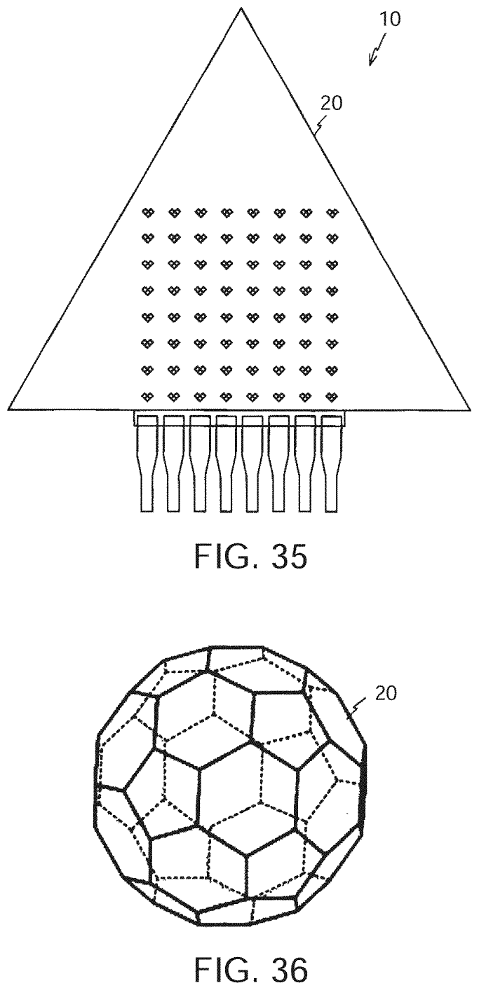

In the embodiment described above, a case is described in which the light emitting panel 20 of the light emitting device 10 is in the shape of a quadrangle. The invention is not limited thereto, and for example, as illustrated in FIG. 35, the light emitting panel 20 may be in the shape of a triangle. In addition, the light emitting panel 20 may be in the shape of a polygon such as a pentagon or a hexagon. The light emitting panel 20 is formed into the shape of a triangle or a hexagon, and thus, as illustrated in FIG. 36, the light emitting panel can be combined into the shape of a polyhedron such as a tetrahedron or an octahedron.

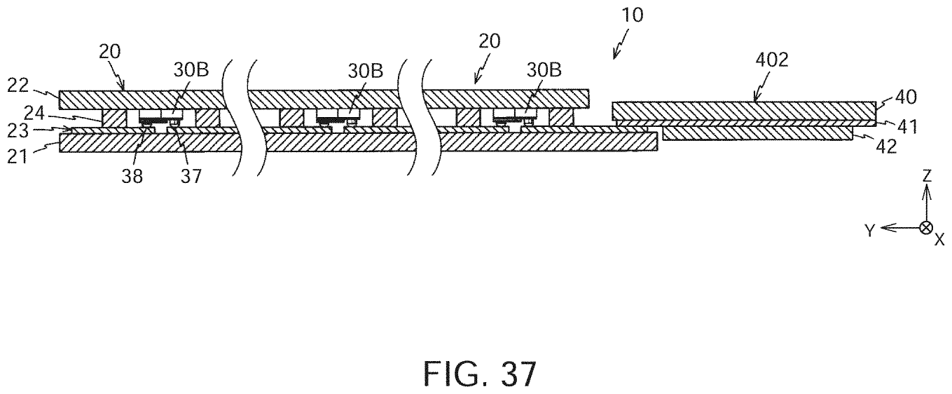

In the embodiment described above, a case is described in which the resin layer 24 is formed without a gap between the substrates 21 and 22. The invention is not limited thereto, and the resin layer 24 may be partially formed between the substrates 21 and 22. For example, the resin layer 24 may be formed only around the light emitting element. In addition, for example, as illustrated in FIG. 37, the resin layer 24 may be formed to configure a spacer that surrounds the light emitting elements 30R, 30G, and 30B.

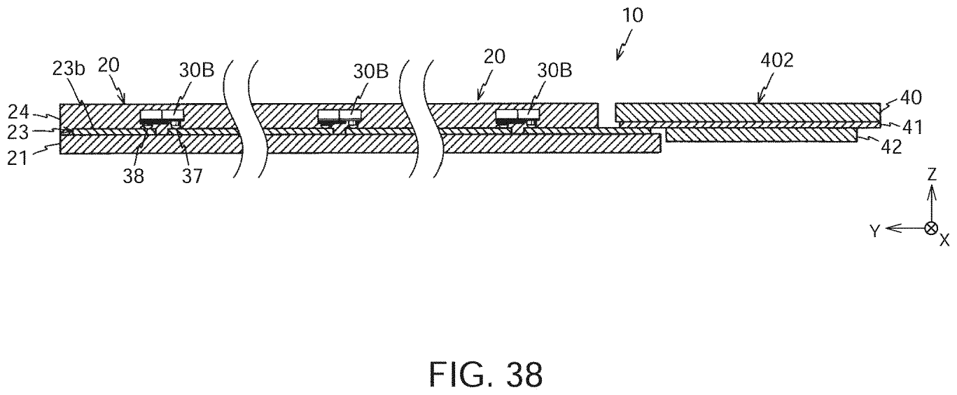

In the embodiment described above, a case is described in which the light emitting panel 20 of the light emitting device 10 includes the substrates 21 and 22, and the resin layer 24. The invention is not limited thereto, and as illustrated in FIG. 38, the light emitting panel 20 may include only the substrate 21, and the resin layer 24 retaining the light emitting elements 30R, 30G, and 30B.

In the embodiment described above, a case is described in which the resin layer 24 is formed of a thermosetting resin sheet 241 and a thermosetting resin sheet 242. The invention is not limited thereto, and the resin layer 24 may be formed of a thermoplastic resin sheet. In addition, the resin layer 24 may be formed of both of a thermosetting resin and a thermosetting resin.

In the embodiment described above, a case is described in which the conductor layer 23 is formed of a metal material such as copper (Cu) or silver (Ag). The invention is not limited thereto, and the conductor layer 23 may be formed of a transparent material having conductivity such as indium tin oxide (ITO).

In the embodiment described above, as illustrated in FIG. 1, a case is described in which the light emitting device 10 includes the point light sources Gmn that are arranged into the shape of a matrix of eight rows and eight columns. The invention is not limited thereto, and the light emitting device 10 may include the point light sources Gmn that are arranged in nine or more rows or eight or more columns.

In the embodiment described above, as illustrated in FIG. 2, a case is described in which three light emitting elements 30R, 30G, and 30B are arranged into the shape of L. The arrangement of the light emitting elements is not limited thereto, and for example, three light emitting elements 30R, 30G, and 30B may be arranged linearly or to be simply close to each other.

In the embodiment described above, a case is described in which the light emitting elements 30G and 30B are adjacent to the light emitting element 30R. The array order of the light emitting element 30 is not limited thereto. For example, the other light emitting element 30 may be adjacent to the light emitting element 30G or the light emitting element 30B.

In addition, as illustrated in FIG. 10, the light emitting panel 20 of the light emitting device 10 is formed by heating and pressure bonding each of the substrates 21 and 22 through the resin sheets 241 and 242, under a vacuum atmosphere. Accordingly, as illustrated in FIG. 10, in the substrates 21 and 22, a portion in which the light emitting element 30R is positioned protrudes to the outside. For this reason, outer surfaces 21b and 22b and inner surfaces 21a and 22b of the substrates 21 and 22 are bent to surround the light emitting element 30R. Therefore, light from the light emitting element 30R is diffused by a lens effect due to the deformation of the substrates 21 and 22. In addition, the refractive index n1 of the substrates 21 and 22 is different from a refractive index n2 of the resin layer 24. For this reason, light is diffused on a boundary between the substrates 21 and 22 and the resin layer 24. In addition, light from the light emitting element 30R is also diffused due to diffused reflection on the electrode or the bump, or the fact that the substrates 21 and 22 or the resin layer 24 is not completely transparent.

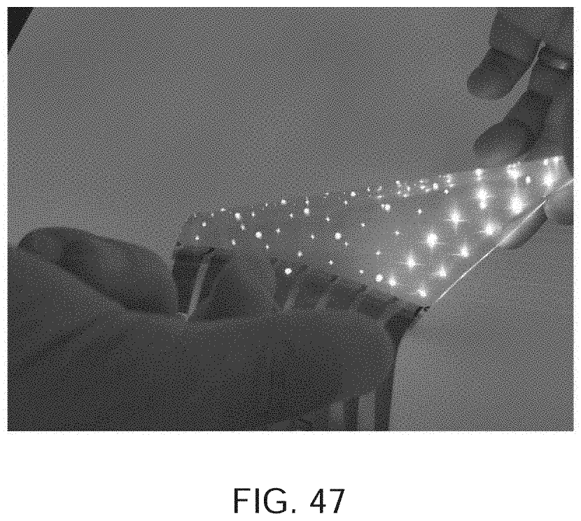

In addition, the light emitting device according to this embodiment can be folded as illustrated in the picture of FIG. 47. Accordingly, there is a case where the light emitting panel is visually confirmed through the light emitting panel. In addition, the same applies to a case where the light emitting devices 10 are overlappingly arranged.

Some embodiments of the invention are described, but such embodiments are presented as an example and are not intended to limit the scope of the invention. Such novel embodiments can be implemented in other various forms, and various omissions, replacements, and changes can be made without departing from the gist of the invention. Such embodiments and modifications thereof are included in the scope or the gist of the invention, and are included in the invention described in the claims and the equivalents thereof.

### EXPLANATIONS OF LETTERS OR NUMERALS

10 LIGHT EMITTING DEVICE
20, 20A LIGHT EMITTING PANEL
20B PANEL
21, 22 SUBSTRATE
21a, 22a FIRST SURFACE
21b, 22b SECOND SURFACE
23 CONDUCTOR LAYER
23a TO 23h CONDUCTOR PATTERN
24 RESIN LAYER
30R, 30G, 30B LIGHT EMITTING ELEMENT
31 BASE SUBSTRATE
32 N TYPE SEMICONDUCTOR LAYER
33 ACTIVE LAYER
34 P TYPE SEMICONDUCTOR LAYER
35, 36 PAD ELECTRODE
37, 38 BUMP
40 BASE SUBSTRATE
41 CONDUCTOR PATTERN
42 COVERLAY
230 VIA CONDUCTOR
241, 242 RESIN SHEET
300 PAPER
401 TO 408 FIXABLE CABLE
500 SHOWCASE
501 CURVED GLASS
600 TAIL LAMP
700 SCREW
R1 TO R8, G1 TO G8, B1 TO B8 INDIVIDUAL LINE PATTERN
CM COMMON LINE PATTERN
CM1 MAIN PORTION
CM2 BRANCH PORTION
D1, D2 DUMMY LINE PATTERN
Gmn POINT LIGHT SOURCE
Lx LINE
Ly LINE
L0 LIGHT DISTRIBUTION CURVE
M MIRROR
MG, PD CONNECTION PAD

1. A light emitting device, comprising:
a first substrate having light transmittivity and flexibility, a conductor layer being formed on the first substrate;
a second substrate having light transmittivity and flexibility, and being arranged to face the first substrate;
a plurality of light emitting elements including an electrode connected to the conductor layer, and configuring a point light source by being arranged between the first substrate and the second substrate into the shape of a matrix; and
a resin layer having light transmittivity and flexibility, and retaining the plurality of light emitting elements by being arranged between the first substrate and the second substrate,
wherein a distance between the point light sources adjacent to each other is 0.3 cm to 3.2 cm.

2. The light emitting device according to claim 1,
wherein the point light source is arranged into the shape of a matrix of four or more rows and four or more columns, and emits light in a predetermined light emitting pattern.

3. A light emitting device, comprising:
a first substrate having light transmittivity and flexibility, a conductor layer being formed on the first substrate;
a plurality of light emitting elements having light transmittivity and flexibility, including an electrode connected to the conductor layer, and configuring a point light source on the first substrate; and
a resin layer having light transmittivity and flexibility, and retaining the plurality of light emitting elements on the first substrate,
wherein an array pitch of the point light source is greater than or equal to 5 mm, one of the adjacent point light sources is turned on, and the other is turned off.

4. The light emitting device according to claim 3,
wherein the array pitch of the point light source is greater than or equal to 10 mm.

5. The light emitting device according to claim 3,
wherein the array pitch of the point light source is greater than or equal to 10.2 mm.

6. The light emitting device according to claim 3,
wherein the point light source is turned on for each column or each row.

7. A light emitting device, comprising:
a first substrate having light transmittivity and flexibility, a conductor layer being formed on one first surface;
a second substrate having light transmittivity and flexibility, one first surface being arranged to face the first substrate;
a plurality of light emitting elements including an electrode connected to the conductor layer, and being arranged between the first substrate and the second substrate; and
a retention member retaining the first substrate and the second substrate, and the plurality of light emitting elements,
wherein an intensity of light exiting from the plurality of light emitting elements, and being totally reflected by being incident on the other second surface of the first substrate or the second substrate at an incident angle of a critical angle, is greater than or equal to 0.7 with respect to a peak value of light from the light emitting element.

8. The light emitting device according to claim 7,
wherein the critical angle θ and a refractive index n1 of the substrate are in a relationship represented by the following expression, and a relative intensity of a light distribution curve of the light emitting element at the critical angle θ is greater than or equal to 0.9 of the most intensive radiant light peak value.
Sin θ=1/n1

9. The light emitting device according to claim 1,
wherein the conductor layer includes a mesh pattern, and
a transmittance of the resin layer including the conductor layer is greater than or equal to 80%.

10. The light emitting device according to claim 1,
wherein the first substrate and the second substrate are bent to surround the light emitting element.

11. The light emitting device according to claim 1,
wherein a refractive index of the first substrate and the second substrate is different from a refractive index of the resin layer.

12. The light emitting device according to claim 1,
wherein light from the light emitting element is diffused in the first substrate and the second substrate, and the resin layer due to a transparency.

13. The light emitting device according to claim 1,
wherein the electrode of the light emitting element is connected to the conductor layer through a bump, and
light from the light emitting element is reflected on the electrode and the bump.

14. A tail lamp of an automobile, comprising:
a light emitting device provided with a first substrate having light transmittivity and flexibility, a conductor layer being formed on the first substrate, a second substrate having light transmittivity and flexibility, and being arranged to face the first substrate, a plurality of light emitting elements including an electrode connected to the conductor layer, and configuring a point light source by being arranged between the first substrate and the second substrate, and a resin layer having light transmittivity and flexibility, and retaining the plurality of light emitting elements by being arranged between the first substrate and the second substrate, a distance between the adjacent point light sources being 0.3 cm to 3.2 cm; and
another light emitting unit arranged on a back surface of the light emitting device,
wherein light exiting from the another light emitting unit is transmitted through the light emitting device, and exits to the outside.

15. The tail lamp of the automobile according to claim 14,
wherein another light source is a mirror on a back surface of the light emitting device, and light exiting from the light emitting device to the mirror is reflected on the mirror, and then, is transmitted through the light emitting device, and exits to the outside.

16. The tail lamp of the automobile according to claim 15,
wherein an array pitch of the point light source is greater than or equal to 5 mm, one of the adjacent point light sources is turned on, and the other is turned off.

17. The tail lamp of the automobile according to claim 14,
wherein an intensity of light exiting from the plurality of light emitting elements, and being totally reflected by being incident on the other second surface of the first substrate or the second substrate at an incident angle of a critical angle, is greater than or equal to 0.7 with respect to a peak value of light from the light emitting element.

18. The tail lamp of the automobile according to claim 14,
wherein the critical angle θ and a refractive index n1 of the substrate are in a relationship represented by the following expression, and a relative intensity of a light distribution curve of the light emitting element at the critical angle θ is greater than or equal to 0.9 of the most intensive radiant light peak value.
Sin θ=1/n1
